(19) United States
(12) Patent Application Publication
(10) Pub. No.: US 2017/0107331 A1
(43) Pub. Date: Apr. 20, 2017

(54) Methods For Preparing Articles And Associated Articles Prepared Thereby

(71) Applicant: Dow Corning Corporation, Midland, MI (US)

(72) Inventors: CHAD M. AMB, HUDSON, WI (US); RANJITH SAMUEL JOHN, CUPERTINO, CA (US); WILLIAM K. WEIDNER, BAY CITY, MI (US)

(73) Assignee: Dow Corning Corporation, Midland, MI (US)

(21) Appl. No.: 15/316,997

(22) PCT Filed: Jun. 16, 2015
(86) PCT No.: PCT/US2015/035924

§ 371 Date: Dec. 7, 2016

Related U.S. Application Data
(60) Provisional application No. 62/020,882, filed on Jul. 3, 2014.

(51) Int. Cl. C08G 77/00; G03F 7/20; G02B 6/132; G02B 6/122; G02B 6/30; G03F 7/16; G03F 7/26

(52) U.S. Cl. CPC C08G 77/80; G03F 7/162; G03F 7/2002; G03F 7/26; G02B 6/122; G02B 6/30; G02B 6/132

(57) ABSTRACT

A method for preparing an article includes applying a first composition on a substrate to form a first layer, and applying a curing condition to a target portion without applying the curing condition to a non-target portion of the first layer to form a first contrast layer. A second composition is then applied on the first contrast layer to form a second layer, and a curing condition is applied to a target portion without applying the curing condition to a non-target portion of the second layer and first contrast layer to form a second contrast layer. A third composition can optionally be applied and cured on the second contrast layer to form a third contrast layer having a cured and uncured portion in the same manner. The uncured portions of these contrast layers are then selectively removed to prepare the article.

The present invention generally relates to methods for preparing articles, and associated articles prepared thereby.

Polymer waveguides are identified as a key technology to displace copper interconnects in printed circuit board (PCB) technology as well as in Silicon Photonics due to the ability to use the principle of total internal reflection of light for faster data transmission. PWGs represent a key advantage as losses and energy for data transmission via copper is the primary bottleneck for next generation datacenters and mobile applications.

The conventional fabrication of a PWG includes a series of steps where a bottom clad layer of refractive index RI¹ is deposited on a substrate and selectively irradiated to form cross linked structures at specific locations. The clad layer is then developed using a solvent which removes the uncured areas of the clad layer (i.e., areas which were not cross linked). This is followed by an optional bake step to remove solvents from the developed clad layer. A second layer, or core layer, with refractive index RI² (which is greater than RI¹) is then deposited on top of the first clad layer and selectively cross linked to create a first stacked layer. The core layer is then developed using solvent to selectively remove uncured areas. This is followed by a third layer, the top clad with refractive index RI¹ (same as first layer) or optionally RI³ (which is different from RI¹ & RI²) for intermixed core and top clad. The third layer is deposited on the stacked layers (layer 1 & layer 2) and selectively irradiated to create a complete stack of waveguide features comprising of bottom clad-core-top clad enabling for the stack to be used for optical data transmission in high performance computing and other applications

Structuring of the clad layer allows for the alignment and connectorization of the polymer waveguides to ferrules which connect to optical sources and interconnects. The structuring of clad wherein the irradiated clad surface is solvent developed, which may cause adhesion challenges when coating the core (second optical) layer onto the developed clad. This may result in failure to fabricate fully functional optical waveguides. Additionally, subsequent thermal steps for solvent evaporation can lead to excessive shrinkage and curling of flexible substrates such as FR4 and polyimide which lead to cracking and delamination during embedding of waveguides in PCB or during high temperature processing such as solder reflow, thermal shock etc where the waveguide material is exposed to temperatures in excess of 250° C.

Another challenge that has been identified is the reliability of polymer waveguides during and post integration/embedding of the same in a PCB or Silicon Photonic package architecture. The conventional PCB manufacturing has steps where multiple layers of FR4, polyimide and prepreg's are laminated at relatively high temperatures (180° C.-200° C.) which are then followed by drilling of thru-hole vias for application of solder paste to form electrical connections. The process of lamination and drilling causes the embedded polymer films to crack and fail during integration due to high levels of stress associated as well as large coefficient of thermal expansion (CTE) mismatches between the FR4, polyimide and the polymer waveguide materials. Additionally, in Silicon Photonics packaging, the PWG's are exposed to processes such as solder reflow where the reflow temperatures can be 280° C. or higher which can lead to failure.

The present invention addresses certain of the challenges identified above.

### SUMMARY OF THE INVENTION

The present invention provides methods for preparing an article.

In one embodiment, the method comprises applying a first composition having a first refractive index (RI¹) on a substrate to form a first layer comprising the first composition on the substrate. The method further comprises applying a curing condition to a target portion of the first layer, without applying the curing condition to a non-target portion of the first layer, to form a first contrast layer including at least one cured portion and at least one uncured portion. In addition, the method comprises applying a second composition having a second refractive index (RI²) on the contrast layer to form a second layer. The method further comprises applying a curing condition to a target portion of the second layer, without applying the curing condition to a non-target portion of the second layer and first contrast layer, to form a second contrast layer including at least one cured portion and at least one uncured portion. The method then comprises selectively removing the at least one uncured portion of the first and second contrast layer to prepare the article, wherein the article sequentially comprises the substrate, the first contrast layer having the at least one cured portion and not having the at least one uncured portion, and the second contrast layer having the at least one cured portion and not having the at least one uncured portion.

In another embodiment, the method comprises applying a first composition having a first refractive index (RI¹) on a substrate to form a first layer comprising the first composition on the substrate. The method further comprises applying a curing condition to a target portion of the first layer, without applying the curing condition to a non-target portion of the first layer, to form a first contrast layer including at least one cured portion and at least one uncured portion. In addition, the method comprises applying a second composition having a second refractive index (RI²) on the contrast layer to form a second layer. The method further comprises applying a curing condition to a target portion of the second layer, without applying the curing condition to a non-target portion of the second layer and first contrast layer, to form a second contrast layer including at least one cured portion and at least one uncured portion. Still further, the method comprises applying a third composition having a third refractive index (RI³) on the second contrast layer to form a third layer. The method further comprises applying a curing condition to a target portion of the third layer, without applying the curing condition to a non-target portion of the third layer and without applying the curing condition to the uncured portions of the second and first contrast layer, to form a third contrast layer including at least one cured portion and at least one uncured portion. The method then comprises selectively removing the at least one uncured portion of the first, second and third contrast layer to prepare the article, wherein the article sequentially comprises the substrate, the first contrast layer having the at least one cured portion and not having the at least one uncured portion, the second contrast layer having the at least one cured portion and not having the at least one uncured portion, and the third contrast layer having the at least one cured portion and not having the at least one uncured portion.

In certain of these embodiments, the step of selectively removing the at least one uncured portion of the first, second and third contrast layer (if present) to prepare the article comprises selectively and simultaneously removing the at least one uncured portion of the first, second and third contrast layer (if present).

In certain of these embodiments, the first (RI¹), second (RI²), and/or third (RI³) refractive indices may be the same or different from one another.

The method according to the invention prepares articles having excellent optical and physical properties.

In addition, the method prepares articles at a lesser cost and with fewer steps than conventional methods required to prepare similar articles. Notably, the removal of the uncured portions of first, second and third contrast layer (if present) after application of the each of the layers removes one or two (if the third contrast layer is present) removal steps from the process. Associated therewith, elimination of the step to remove uncured portions of the first contrast layer, prior to application of the second layer onto the first contrast layer, improves adhesion of the second layer (and subsequently the second contrast layer) to the first contrast layer. Similarly, elimination of the step to remove uncured portions of the second contrast layer, prior to application of the third layer onto the second contrast layer, improves adhesion of the third layer (and subsequently the third contrast layer) to the second contrast layer. This may result in a decrease in the failure rate in fabricating fully functional optical waveguides.

The invention method is particularly suitable for preparing optical articles, such as waveguides, and in particular for forming articles having stacked waveguides.

### BRIEF DESCRIPTION OF THE DRAWINGS

Other advantages and aspects of this invention may be described in the following detailed description when considered in connection with the accompanying drawings wherein:

FIGS. 1-5 illustrate perspective views at different stages of a method for forming article in accordance with one embodiment of the present invention;

FIGS. 6-11 illustrate perspective views at different stages of a method for forming article in accordance with another embodiment of the present invention;

FIGS. 12-16 illustrate perspective views at different stages of a method for forming article in accordance with yet another embodiment of the present invention;

FIGS. 17-21 illustrate perspective views at different stages of a method for forming article in accordance with still another embodiment of the present invention;

FIGS. 22-25 illustrate perspective views at different stages of a method for forming article in accordance with still yet another embodiment of the present invention; and

FIG. 26 illustrates a perspective view of the further processing of the article of FIG. 25 to attach a fiber core in accordance with one embodiment of the present invention.

### DETAILED DESCRIPTION OF THE INVENTION

The present invention provides methods for preparing an article. The methods according to the present invention prepare articles having excellent optical and physical properties. For example, the methods are particularly suitable for preparing optical articles, such as waveguides, and in particular for forming articles having stacked waveguides. However, the methods are not limited to such optical articles and may be utilized to form articles suitable for use in numerous different applications, whether or not a contrast in refractive index is desired or used.

The present invention is illustrated in the representative Figures. However, the relative size and shape of the individual components identified by the reference numerals in any one or more of the Figures below is not intended to be limited to the depiction illustrated.

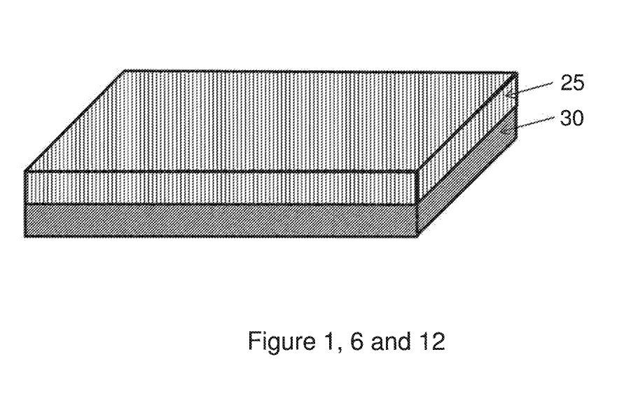

In a first embodiment of the present invention, as illustrated in FIGS. 1 to 5, a method for forming an article 20 having two layer patterning is described and illustrated.

As shown in FIG. 1, the method first comprises applying a first composition having a first refractive index (RI¹) on a substrate 30 to form a first layer 25. The first composition is a curable composition and may be selected based at least on the desired first refractive index and other factors, e.g. desired cure mechanism, as described below.

The first composition may be applied on the substrate 30 via various methods. For example, in certain embodiments, the step of applying the first composition on the substrate 30 comprises a wet coating method. Specific examples of wet coating methods suitable for the method include dip coating, spin coating, flow coating, spray coating, roll coating, gravure coating, sputtering, slot coating, and combinations thereof.

The substrate 30 may be rigid or flexible. Examples of suitable rigid substrates include inorganic materials, such as glass plates; glass plates comprising an inorganic layer; ceramics; wafers, such as silicon wafers, and the like. In other embodiments, it may be desirable for the substrate to be flexible. In these embodiments, specific examples of flexible substrates include those comprising various organic polymers. From the view point of transparency, refractive index, heat resistance and durability, specific examples of flexible substrates include those comprising polyolefins (polyethylene, polypropylene, etc.), polyesters (poly(ethylene terephthalate), poly(ethylene naphthalate), etc.), polyamides (nylon 6, nylon 6,6, etc.), polystyrene, poly(vinyl chloride), polyimides, polycarbonates, polynorbornenes, polyurethanes, poly(vinyl alcohol), poly(ethylene vinyl alcohol), polyacrylics, celluloses (triacetylcellulose, diacetylcellulose, cellophane, etc.), or interpolymers (e.g. copolymers) of such organic polymers. As understood in the art, the organic polymers recited above may be rigid or flexible. Further, the substrate may be reinforced, e.g. with fillers and/or fibers. The substrate may have a coating thereon, as described in greater detail below. The substrate may be separated from the article to give another invention article sequentially comprising the contrast layer and cured second layer and lacking the substrate, if desired, or the substrate may be an integral portion of the article.

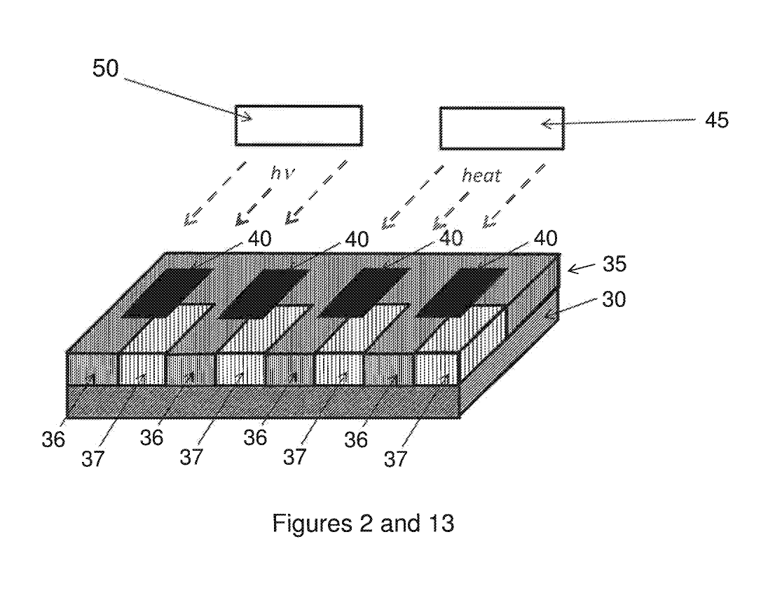

Next, as shown in FIG. 2, the method further comprises applying a curing condition to a target portion of the first layer 25, without applying the curing condition to a non-target portion of the first layer, to form a first contrast layer 35 including at least one cured portion 36 and at least one uncured portion 37. The step of applying the curing condition to the target portion of the first layer, without applying the curing condition to a non-target portion of the first layer, may alternatively be referred to herein as “selectively curing” the first layer to form the first contrast layer 35. Generally, the first contrast layer 35 includes one or more cured portions 36 and one or more uncured portions 37, and the first layer 25 may include a corresponding number of target portions non-target portions for forming the one or more cured portions 36 and one or more uncured portions 37 of the first contrast layer 35, respectively. For purposes of clarity, the at least one cured portion 36 may be referred to herein merely as “the cured portion,” and the at least one uncured portion 37 may be referred to herein merely as “the uncured portion,” and this terminology encompasses embodiments where the first contrast layer 35 includes more than one cured portion 36 and/or more than one uncured portion 37, respectively.

The method by which the first layer is selectively cured, and thus the curing condition utilized, is determined by at least the first composition. For example, in certain embodiments, the first composition and the first layer 25 formed from the composition are curable upon exposure to active-energy rays, i.e., the first layer is selectively cured by selectively irradiating the first layer with active-energy rays from a source 50 capable of emitting active-energy rays. The active-energy rays may comprise ultraviolet rays, electron beams, or other electromagnetic waves or radiation.

Alternatively, the first layer may be thermally cured. In these embodiments, the first layer 25 is selectively cured by selectively heating the first layer 25, e.g. selectively heating the first layer 25 with a heating element. Examples of suitable heating elements (shown generally as 45 in FIG. 2) include resistive or inductive heating elements, infrared (IR) heat sources (e.g., IR lamps), and flame heat sources. An example of an inductive heating element is a radio frequency (RF) induction heating element.

Irradiation is typically preferred due to the ease with which the first layer 25 may be selectively cured by applying a curing condition to a target portion of the first layer 25, without applying the curing condition to a non-target portion of the first layer, to form the first contrast layer 35. In these embodiments, one or more photo masks are typically utilized in the selective curing of the target portion of the first layer. Photo masks generally have a defined pattern for transmitting active-energy rays therethrough and a complementary pattern for blocking transmission of active-energy rays. For example, the photo mask includes portions that allow for active-energy rays to pass therethrough, and portions that block active-energy rays from passing therethrough, such that the defined pattern can be transferred via selectively curing. The portions of the photo mask that allow for active-energy rays to pass therethrough are aligned with the target portion of the first layer 25, and the complementary portions of the photo mask 40 that block transmission of active-energy rays are aligned with the non-target portion of the first layer 25. When irradiation is utilized to selectively cure the first layer 25, the first composition may be referred to as a photoresist, and the photoresist may be a positive resist or a negative resist. Such a method may be referred to as photolithography.

Alternatively, the photo mask utilized may simply comprise a pattern for blocking transmission of active-energy rays (i.e., the photo mask consists of the complementary portion as described in the previous paragraph), and such a photo mask is positioned relative to the source 50 of the active-energy rays to block transmission of the active energy rays to the non-target portion of the first layer 25 while allowing transmission of active-energy rays directly to the target portion of the first layer 25. A source 50 of ultraviolet radiation may comprise a high-pressure mercury lamp, medium-pressure mercury lamp, Xe-Hg lamp, or a deep UV lamp.

Alternatively, when heat is utilized in the selective curing of the target portion of the first layer 25 through the heating element 45, a thermal mask (or heat mask) or thermal insulator template may be utilized in a fashion similar to the photo mask. As illustrated in the Figures, including in FIG. 2, the photo mask and/or thermal mask are collectively illustrated in the Figures and described herein as mask 40. In particular, the thermal mask 40 may include portions that allow for the target portion of the first layer 25 to be selectively cured to form the cured portion 36 of the first contrast layer 35 while isolating the non-target portion of the first layer such that the non-target portion remains uncured (i.e., the uncured portions 37) in the first contrast layer 35 after selectively curing the first layer 25.

The step of selectively curing the first layer 25 via active-energy rays generally comprises exposing the target portion of the first layer 25 to radiation from the source 50 at a dosage sufficient to form the cured portion 36 of the first contrast layer 35. The dosage of radiation for selectively curing the first layer 25 is typically from 100 to 8000 millijoules per centimeter squared (mJ/cm²). In certain embodiments, heating may be used in conjunction with irradiation for selectively curing the first layer 25 through the use of the afore-mentioned heating element 45. For example, the first layer 25 may be heated before, during, and/or after irradiating the first layer 25 with active-energy rays. While active energy-rays generally initiate curing of the first layer 25, residual solvents may be present in the first layer, which may be volatilized and driven off by heating. Typical heating temperatures are in the range of from 50 to 200 degrees Celsius (° C.). If heat is utilized prior to irradiation, the heating step may be referred to as a pre-baking step, and is generally utilized only to remove any residual solvent from the first layer 25. Said differently, heat is generally utilized in the pre-baking step only for removing solvent, but not for curing or selectively curing the first layer 25. Curing refers to cross-linking via forming covalent bonds between molecules.

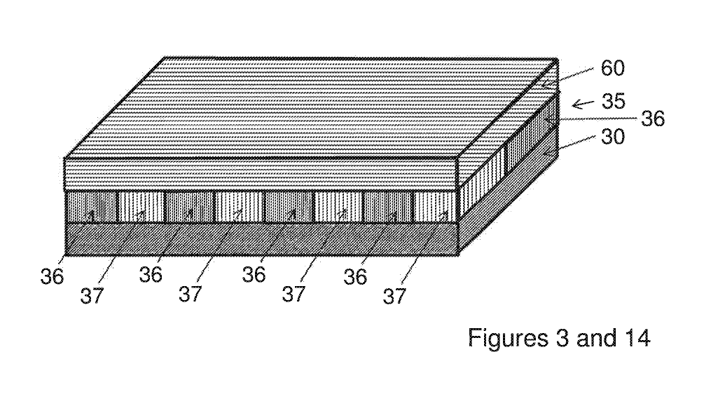

Referring now to FIG. 3, the method further comprises applying a second composition having a second refractive index (RI²) on the first contrast layer 35 to form a second layer 60. In certain embodiments, RI² and RI¹ are different from one another, and in certain embodiments RI² is greater than RI¹ (i.e., RI²>RI¹) when measured at the same temperature and wavelength, while in certain other embodiments RI¹ is greater than RI² (i.e., RI¹>RI²). In still further embodiments, RI′=RI² but wherein the first composition and second composition may be different in some other manner, such as for example different in terms of mechanical properties when the first composition and second composition are cured. The actual values corresponding to RI² and RI¹ are not particularly important.

Notably, refractive index is generally a function of not only the substitution within the particular composition, but also of a cross-link density of the cured product derived from the respective composition. To this end, the refractive index of the cured portion of the first composition may be different than RI¹. However, the refractive index gradient is generally maintained before and after curing. For comparison purposes, the refractive indices are measured at a same temperature and wavelength of light in accordance with ASTM D542-00, optionally at a wavelength of 589.3 nm.

The second composition may be applied on the first contrast layer 35 to form a second layer 60 by any of the wet coating methods introduced above relative to the first composition. The steps of applying the first and second compositions may be the same as or different from one another.

In certain embodiments (shown in alternative embodiments below), the uncured portion 37 of the first contrast layer 35 may intermix with the second composition to form an intermixed portion, and thus the uncured portion 37 and the second layer 60 each comprise a mixture of the first composition and the second composition and have a refractive index RI having a value between RI¹ and RI² (when RI¹ and RI² are different). The degree of intermixing of the uncured portion 37 and the second layer 60 is dependent upon numerous factors, including the viscosity of the first composition and the second composition, as well as the time that the uncured portion 37 and second layer 60 are allowed to intermix.

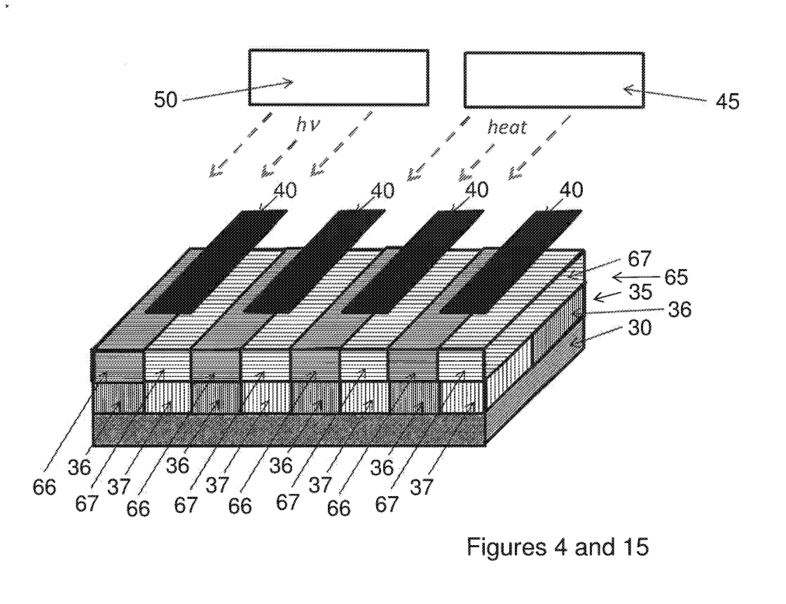

Next, as shown in FIG. 4, the method further comprises applying a curing condition to a target portion of the second layer 60, without applying the curing condition to a non-target portion of the second layer 60 and without applying a curing condition to the at least one uncured portion 37 of the first contrast layer 35, to form a second contrast layer 65 including at least one cured portion 66 and at least one uncured portion 67. For purposes of clarity, the at least one cured portion 66 may be referred to herein merely as “the cured portion,” and the at least one uncured portion 67 may be referred to herein merely as “the uncured portion,” and this terminology encompasses embodiments where the second contrast layer includes more than one cured portion and/or more than one uncured portion, respectively.

In embodiments wherein the uncured portion 37 and first contrast layer intermix to form an intermixed portion, the applied curing condition as described in FIG. 4 thus is applied to a target portion of the intermixed layer, without applying a curing condition to a non-target portion, to form an alternative version of the second contrast layer including at least one cured intermixed portion and at least one uncured intermixed portion.

The method by which the second layer 60 is selectively cured, and thus the curing condition utilized, is determined by at least the second composition. For example, in certain embodiments, the second composition and the second layer formed from the composition are curable upon exposure to active-energy rays, i.e., the second layer is selectively cured by selectively irradiating the second layer with active-energy rays. The active-energy rays, similar to above, may comprise ultraviolet rays, electron beams, or other electromagnetic waves or radiation. Typically, the curing of the target portion of the second layer is by the same method as the curing of the target portion of the first layer.

Similar to the curing of the first layer 25 described above, one or more photo masks (and/or thermal masks) 40 are typically utilized in the selective curing of the target portion of the second layer 60. More specifically, the portions of the photo mask 40 that allow for active-energy rays to pass there through are aligned with the target portion of the second layer 60, and the complementary portions of the photo mask 40 that block transmission of active-energy rays are aligned with the non-target portion of the second layer 60. Alternatively, the portions of the thermal mask 40 that allow for thermal energy to pass there through are aligned with the target portion of the second layer 60, and the complementary portions of the thermal mask 40 that block transmission of thermal energy are aligned with the non-target portion of the second layer 60.

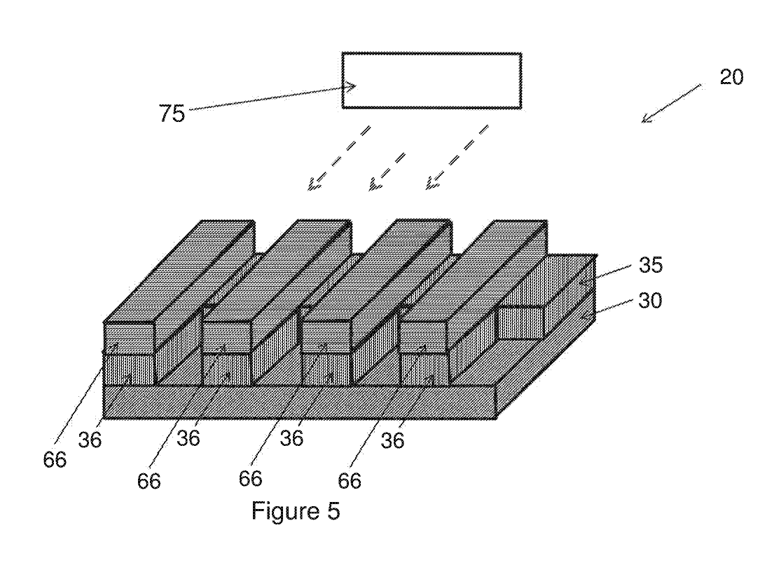

Next, as shown in FIG. 5, the method further includes the step of selectively removing the uncured portions 37 and 67 of the first and second contrast layers 35, 65, therein forming the article 20. In certain embodiments, the uncured portions 37 and 67 are removed in a single step at the same time (i.e., selectively and simultaneously). However, in alternative embodiments, the selective removal may be sequential (i.e., wherein the uncured portion 67 is removed followed by the uncured portion 37, or vice versa, but wherein the removal occurs after both contrast layers 35, 65 have been applied and the uncured portions 37 and 67 formed).

In certain embodiments, such as shown in FIG. 5, the uncured portions 37 and 67 are washed with solvent (shown generally in a container 75 but hereinafter described as solvent 75) in a process otherwise referred to as developing the article 20.

In certain embodiments, the article 20 is developed wherein the multiple applied contrast layers 35 and 65 are soaked in a solvent 75, such as mesitylene or diethylene glycol monoethyl ether acetate, for a sufficient period of time such that the uncured portions 37 and 67 begin to dissolve into the solvent. For example, in certain embodiments, multiple applied layers are soaked for about 2 to 5 minutes. The multiple applied contrast layers 35 and 65 are then rinsed with the same solvent, or another solvent in which the uncured portions 37 and 67 are soluble, thus resulting in the sequential or simultaneous selective removal of the uncured portions 37 and 67, such that the article 20 remains. In addition, in certain embodiments, an optional post-bake may be utilized, wherein the article 20 is heated to a temperature sufficient to remove any residual solvent.

The resultant article 20, in any embodiment above, sequentially comprises the substrate 30, the first contrast layer 35 having the at least one cured portion 36 and not having the at least one uncured portion 37, and the second contrast layer 65 having the at least one cured portion 66 and not having the at least one uncured portion 67.

In a second embodiment of the present invention, an article 90 may be formed having more than two layers, as described below and illustrated in FIGS. 6-11.

Referring first to FIG. 6, similar to the method described in FIG. 1 above, the method for forming the article 90 first comprises applying a first composition having a first refractive index (RI¹) on a substrate 30 to form a first layer 25 comprising the first composition on the substrate 30.

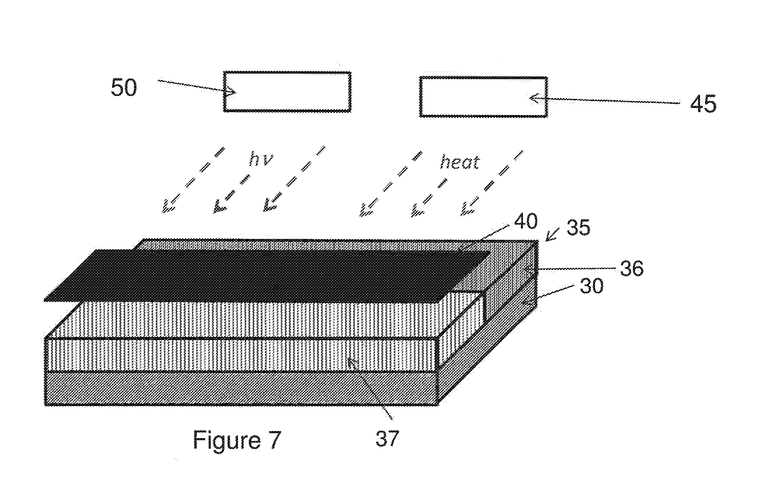

Next, as shown in FIG. 7, similar to the method described in FIG. 2 above, the method further comprises applying a curing condition to a target portion of the first layer 25, without applying the curing condition to a non-target portion of the first layer, to form a first contrast layer 35 including at least one cured portion 36 and at least one uncured portion 37. While FIG. 7 only illustrates a single cured portion 36 and a single uncured portion 37, more than one cured and uncured portions 36, 37 may be introduced in this step. The applicable curing conditions for forming the first contrast layer 35 as illustrated in FIG. 7 are as described above with respect to FIG. 2 of the first embodiment.

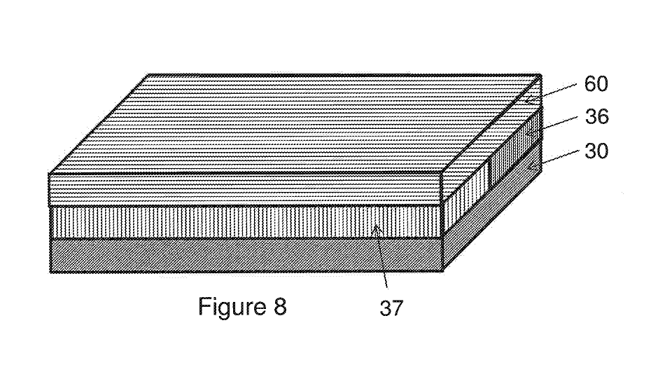

Next, as shown in FIG. 8, similar to the method described in FIG. 3 above, the method further comprises applying a second composition having a second refractive index (RI²) on the first contrast layer 35 to form a second layer 60. Similar to the first embodiment, the first refractive index (RI¹) may be the same or different than the second refractive index (RI²) as described above.

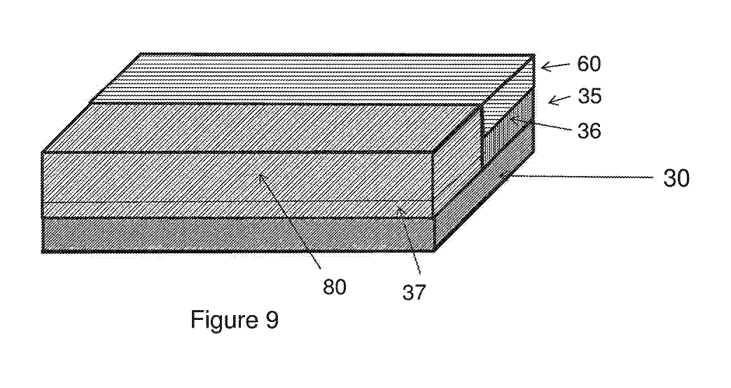

Next, as shown in FIG. 9, at least a portion of the uncured portion 37 of the first contrast layer 35 intermixes with the second composition of the second layer 60 to form an intermixed layer 80. In certain embodiments (not shown), the entirety of the uncured portion 37 of the first contrast layer 35 has been intermixed with the second composition of the second layer 60, but in certain other embodiments, such as shown in FIG. 9, a portion of the uncured portion 37 does not intermix, and hence remains as an uncured portion 37 of the first contrast layer 35 in addition to the intermixed layer 80. The degree of intermixing of the uncured portion 37 and the second layer 60 to form this intermixed layer 80 is dependent upon numerous factors, including the viscosity of the first composition and the second composition, as well as the time that the uncured portion 37 and second layer 60 are allowed to intermix.

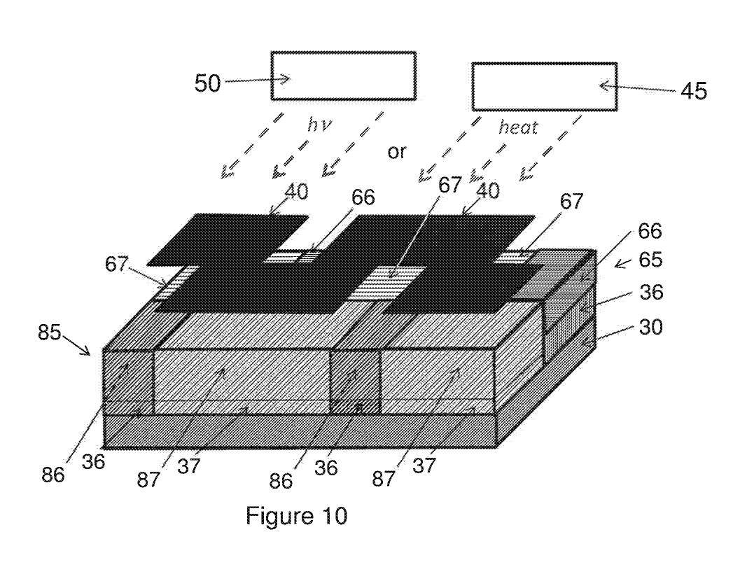

Next, as shown in FIG. 10, the method further comprises applying a curing condition to a target portion of the second layer 60, without applying the curing condition to a non-target portion of the second layer 60 to form a second contrast layer 65 including at least one cured portion 66 and at least one uncured portion 67. At the same time, the curing condition is applied to a target portion of the intermixed layer 80, without applying the curing condition to a non-target portion of the intermixed layer 80, to form an intermixed contrast layer 85 having at least one cured portion 86 and at least one uncured portion 87. The curing conditions for curing second layer 60 and intermixed layer 80 may be as described above in the first embodiment with respect to FIG. 4 and may include at least one photo and/or thermal mask 40.

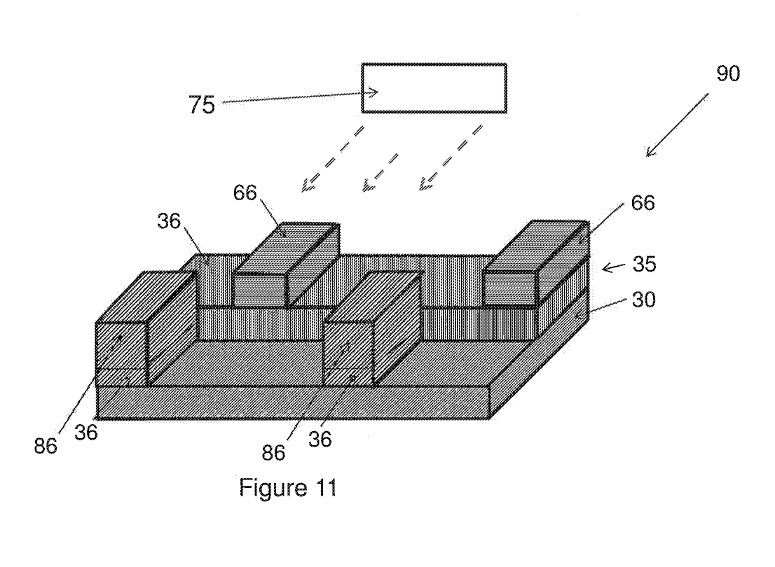

Finally, as shown in FIG. 11, the method further includes the step of selectively removing the uncured portions 37, 67, and 87 of the first and second contrast layers 35, 65 and intermixed contrast layer 85 therein forming the article 90. In certain embodiments, the uncured portions 37, 67, and 87 are selectively removed in a single step at the same time (i.e., selectively and simultaneously). However, in alternative embodiments, the selective removal may be sequential (i.e., wherein the uncured portion 87 is removed followed by the uncured portion 67 is removed followed by the uncured portion 37 is removed, or vice versa, in a single removal step after each of the uncured portions 37, 67, and 87 of the first and second contrast layers 35, 65 and intermixed contrast layer 85 have been formed).

In certain embodiments, the article 90 is developed wherein the multiple applied layers are soaked in a solvent, such as mesitylene or diethylene glycol monoethyl ether acetate, for a sufficient period of time such that the uncured portions 37 and 67 and 87 begin to dissolve into the solvent 75. For example, in certain embodiments, multiple applied layers are soaked for about 2 to 5 minutes. The multiple applied layers are then rinsed with the same solvent, or another solvent in which the uncured portions 37 and 67 and 87 are soluble, thus resulting in the sequential or simultaneous removal of the uncured portions 37 and 67 and 87, such that the article 20 remains. In addition, in certain embodiments, an optional post-bake may be utilized, wherein the article 90 is heated to a temperature sufficient to remove any residual solvent.

The resultant article 90, in any embodiment above, sequentially comprises the substrate 30, the first contrast layer 35 having the at least one cured portion 36 and not having the at least one uncured portion 37, the second contrast layer 65 having the at least one cured portion 66 and not having the at least one uncured portion 67, and the intermixed contrast layer 85 having the at least one cured portion 86 and not having the at least one uncured portion 87.

In still other alternative embodiments, an article 120 may be formed having more than two layers, as illustrated below in the methods associated with the illustrations of FIGS. 12-18.

Referring now to FIGS. 12-15, the method for forming the article 120 begins by forming the first contrast layer 35 and the second contrast layer 65 on the substrate 30 in accordance with the method described above in the first embodiment with respect and illustrated FIGS. 1-4 (also labeled as FIGS. 12-15) and not repeated herein.

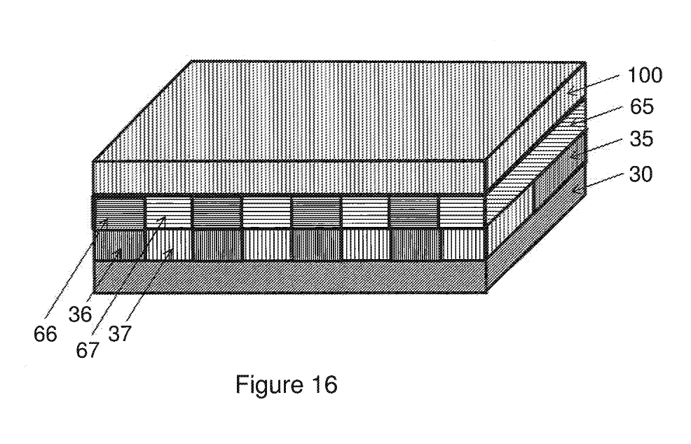

Next, as shown in FIG. 16, a third composition having a third refractive index (RI³) is applied on the second contrast layer 65 to form a third layer 100.

RI³ and RI² may be the same or different from one another, while RI³ and RI¹ may also be the same or different from one another. The actual values corresponding to RI³, RI² and RI¹ are not particularly important.

In certain embodiments, RI² may be greater than RI³ and RI¹ (i.e., RI²>RI¹ and RI²>RI³), such as wherein the second composition forms the core of a polymer waveguide and wherein the first and third compositions form the outer clad of the polymer waveguide. In certain of these embodiments, RI¹ may be greater than RI³ (i.e., RI¹>RI³), the same as RI³ (i.e., RI¹=RI³), or less than RI³ (i.e., RI¹<RI³).

The third composition may be applied as a layer 100 on the second contrast layer 65 by any of the wet coating methods introduced above relative to the first and second composition. The steps of applying the first and second and third compositions may be the same as or different from one another.

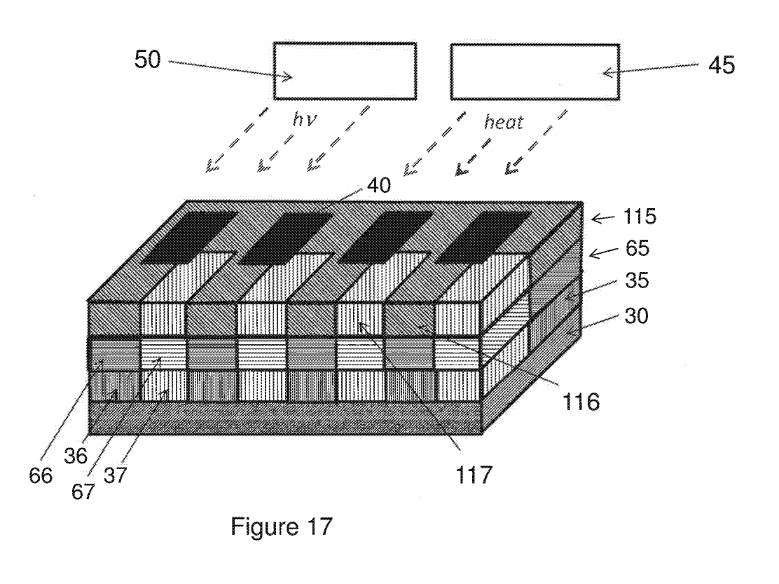

Next, as shown in FIG. 17, the method further comprises applying a curing condition to a target portion of the third layer 100, without applying the curing condition to a non-target portion of the third layer 100 and without applying a curing condition to the at least one uncured portion 37, 67 of the first and second contrast layer 35, 65, to form a third contrast layer 115 including at least one cured portion 116 and at least one uncured portion 117. For purposes of clarity, the at least one cured portion 116 may be referred to herein merely as “the cured portion,” and the at least one uncured portion 117 may be referred to herein merely as “the uncured portion,” and this terminology encompasses embodiments where the third contrast layer 115 includes more than one cured portion 116 and/or more than one uncured portion 117, respectively.

Similar to the first and the second layer 25, 60, the method by which the third layer 100 is selectively cured, and thus the curing condition utilized, is determined by at least the third composition. For example, in certain embodiments, the third composition and the third layer 100 formed from the composition are curable upon exposure to active-energy rays, i.e., the third layer is selectively cured by selectively irradiating the third layer with active-energy rays. The active-energy rays, similar to above, may comprise ultraviolet rays, electron beams, or other electromagnetic waves or radiation. Typically, the curing of the target portion of the third layer 100 is by the same method as the curing of the target portion of the first and second layer 25, 60 as described above. Alternatively, the third layer 100 may be cured by thermal radiation through the use of a heating element 45, as also described above. In conjunction therewith, one or more photo or thermal masks 40 may also be utilized which are aligned with the respective target and non-target portions as described above.

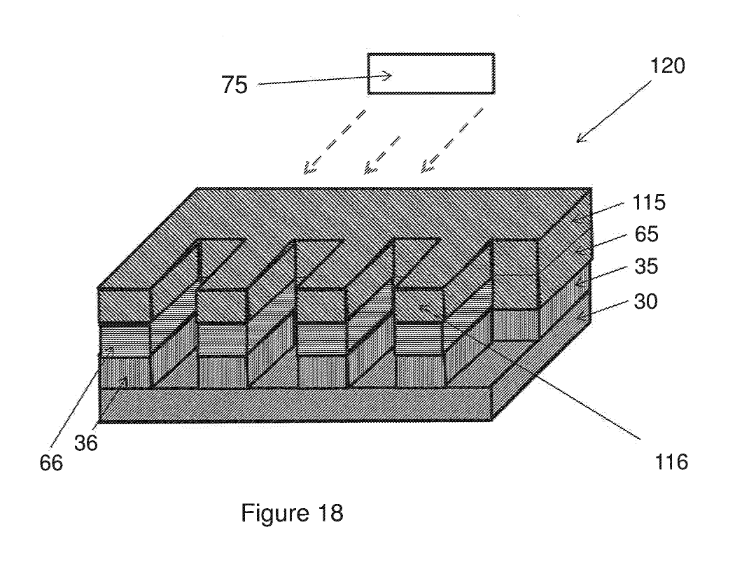

Next, as shown in FIG. 18, and similar to the selective removal steps of FIGS. 5 and 11, the method of this third embodiment further includes the step of selectively removing the uncured portions 37, 67, 117 of the first, second and third contrast layers 35, 65, 115, therein forming the article 120. In certain embodiments, the uncured portions 37, 67, 117 are selectively removed in a single step at the same time (i.e., selectively and simultaneously). However, in alternative embodiments, the selective removal may be sequential (i.e., wherein the uncured portion 117 is first removed followed by the uncured portion 67 and the uncured portion 37, or vice versa, in a single removal step after each of the uncured portions 37, 67, and 117 of the first and second contrast layers 35, 65 and third contrast layers 115 have been formed).

In certain embodiments, the article 120 is developed wherein the multiple applied layers 35, 65, 115 are soaked in a solvent 75, such as mesitylene or diethylene glycol monoethyl ether acetate, for a sufficient period of time such that the uncured portions 37 and 67 and 117 begin to dissolve into the solvent. For example, in certain embodiments, multiple applied layers 35, 65, 115 are soaked for about 2 to 5 minutes. The multiple applied layers 35, 65, 115 are then rinsed with the same solvent, or another solvent in which the uncured portions 37 and 67 and 117 are soluble, thus resulting in the sequential or simultaneous removal of the uncured portions 37 and 67 and 117, such that the article 120 remains. In addition, in certain embodiments, an optional post-bake may be utilized, wherein the article 120 is heated to a temperature sufficient to remove any residual solvent.

The resultant article 120, in any embodiment above, sequentially comprises the substrate 30, the first contrast layer 35 having the at least one cured portion 36 and not having the at least one uncured portion 37, the second contrast layer 65 having the at least one cured portion 66 and not having the at least one uncured portion 67, and the third contrast layer 115 having the at least one cured portion 116 and not having the at least one uncured portion 117.

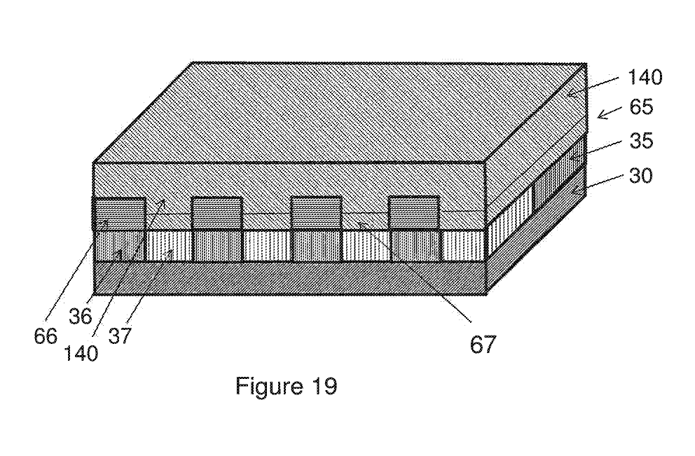

In an alternative arrangement to the steps illustrated in FIGS. 16-18 in this third embodiment, as described in forming an article 150 as illustrated in FIGS. 19-21, at least a portion of the uncured portion 67 of the second contrast layer 65 intermixes with the third composition comprising the third layer 100 to form an intermixed layer 140, as illustrated in FIG. 19.

In certain embodiments (not shown), the entirety of the uncured portion 67 of the second contrast layer 65 has been intermixed with the third composition of the third layer 100 to form the intermixed layer 140, but in certain other embodiments, such as shown in FIG. 19, a portion of the uncured portion 67 does not intermix, and hence remains as an uncured portion 67 of the second contrast layer 65. The degree of intermixing of the uncured portion 67 and the third layer 100 to form this intermixed layer 140 is dependent upon numerous factors, including the viscosity of the second composition and the third composition, as well as the time that the uncured portion 67 and third layer 100 are allowed to intermix.

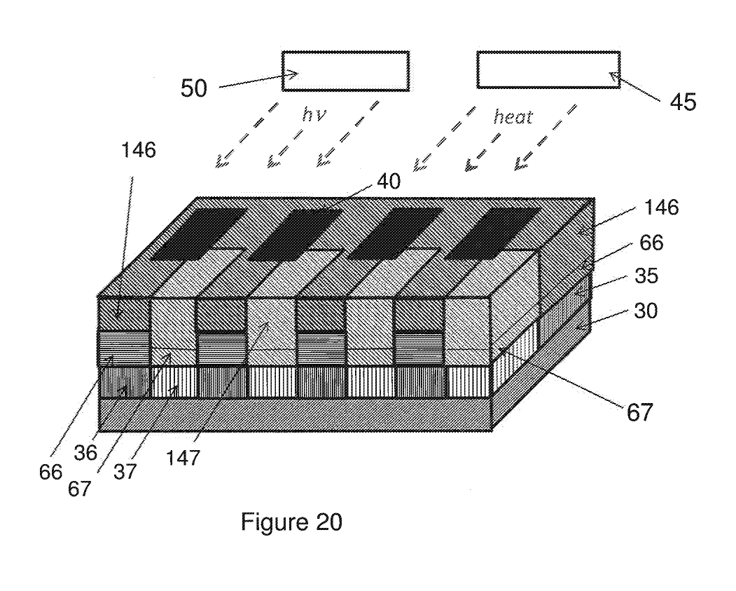

Next, as shown in FIG. 20, the method further comprises applying a curing condition to a target portion of the intermixed layer 140, without applying the curing condition to a non-target portion of the intermixed layer 140 and any remaining uncured portion 67 of the second contrast layer 65, to form an intermixed contrast layer 145 having at least one cured portion 146 and at least one uncured portion 147. The curing conditions for curing intermixed layer 145 may be as described above in the first embodiment with respect to FIG. 4 as irradiation with active energy-rays utilizing a source 50 and/or as thermal curing utilizing a heating element 45 and including the use of the photo and/or thermal mask 40.

Similar to curing of layers as described above, the method by which the intermixed layer 140 is selectively cured, and thus the curing condition utilized, is determined by at least the third composition for forming the intermixed layer 140 and the composition of the uncured portion 67 of the second contrast layer 65 which form the intermixed layer 140. For example, in certain embodiments, the intermixed layer 140 formed is curable upon exposure to active-energy rays from the source 50, i.e., the intermixed layer 140 is selectively cured by selectively irradiating the third layer with active-energy rays. The active-energy rays, similar to above, may comprise ultraviolet rays, electron beams, or other electromagnetic waves or radiation. Typically, the curing of the target portion of the intermixed layer 140 is by the same method as the curing any layer as described above. Alternatively, the intermixed layer 140 may be cured by thermal radiation through the use of a heating element 45, as also described above. In conjunction therewith, one or more photo or thermal masks 40 may also be utilized which are aligned with the respective target and non-target portions as described above.

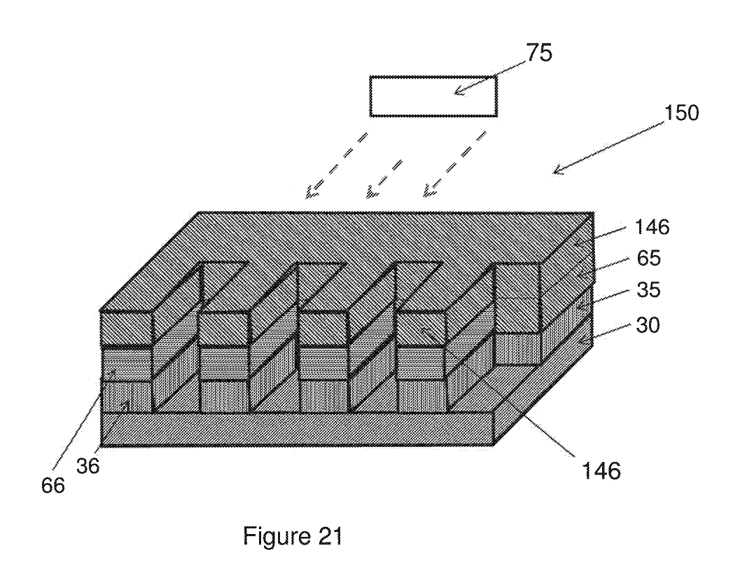

Finally, as shown in FIG. 21, the method further includes the step of selectively removing the uncured portions 37, 67, and 147 of the first and second contrast layers 35, 65 and intermixed contrast layer 145 therein forming the article 150. In certain embodiments, the uncured portions 37, 67, and 147 are selectively removed in a single step at the same time (i.e., selectively and simultaneously). However, in alternative embodiments, the selective removal may be sequential (i.e., wherein the uncured portion 147 is removed followed by the uncured portion 67 and uncured portion 37, or vice versa, in a single removal step after each of the uncured portions 37, 67, and 147 of the first and second contrast layers 35, 65 and intermixed contrast layer 145 have been formed).

In certain embodiments, the article 150 is developed wherein the multiple applied layers 35, 65, 145 are soaked in a solvent 75, such as mesitylene or diethylene glycol monoethyl ether acetate, for a sufficient period of time such that the uncured portions 37 and 67 and 147 begin to dissolve into the solvent. For example, in certain embodiments, multiple applied layers 35, 65, 145 are soaked for about 2 to 5 minutes. The multiple applied layers 35, 65, 145 are then rinsed with the same solvent, or another solvent in which the uncured portions 37 and 67 and 147 are soluble, thus resulting in the sequential or simultaneous removal of the uncured portions 37 and 67 and 147, such that the article 150 remains. In addition, in certain embodiments, an optional post-bake may be utilized, wherein the article 150 is heated to a temperature sufficient to remove any residual solvent.

The resultant article 150, in any embodiment above, sequentially comprises the substrate 30, the first contrast layer 35 having the at least one cured portion 36 and not having the at least one uncured portion 37, the second contrast layer 65 having the at least one cured portion 66 and not having the at least one uncured portion 67, and the intermixed contrast layer 145 having the at least one cured portion 146 and not having the at least one uncured portion 147.

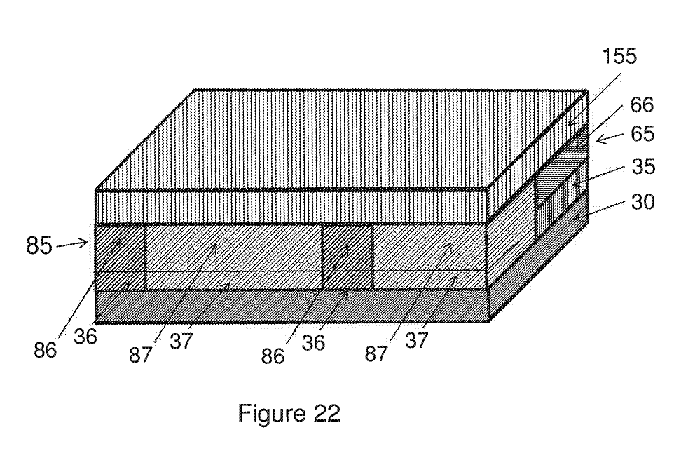

In still another embodiment of the present invention, a three layer patterning article 180 may be formed that builds upon certain steps of the second embodiment described above and illustrated in FIGS. 6-10 as further described and illustrated in FIGS. 22-25.

The method begins according to the process described above with and illustrated in FIGS. 6-10. However as opposed to the removal step described above and illustrated in FIG. 11, the method in this embodiment proceeds with additional steps as illustrated in FIGS. 22-25 and described below.

First, as shown in FIG. 22, a third composition having a third refractive index (RI³) is applied on the second contrast layer 65 and intermixed contrast layer 85 to form a third layer 155, with the third composition having a third refractive index being as described above with respect to FIG. 16.

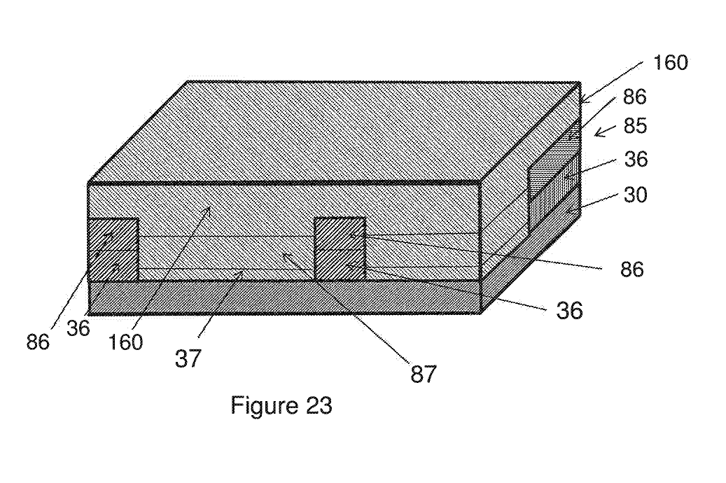

Next, as shown in FIG. 23, at least a portion of the uncured portion 87 of the intermixed contrast layer 85 intermixes with the third composition comprising the third layer 155 to form an intermixed layer 160.

In certain embodiments, the entirety of the uncured portion 87 of the intermixed contrast layer 85 has been intermixed with the third composition of the third layer 155, but in certain other embodiments, such as shown in FIG. 23, a portion of the uncured portion 87 does not intermix, and hence remains as an uncured portion 87 of the intermixed contrast layer 85. The degree of intermixing of the uncured portion 87 and the third layer 155 to form this intermixed layer 160 is dependent upon numerous factors, including the viscosity of the uncured portion 87 of the intermixed contrast layer 85 and the third composition, as well as the time that the uncured portion 87 of the intermixed contrast layer 85 and the third layer 155 are allowed to intermix.

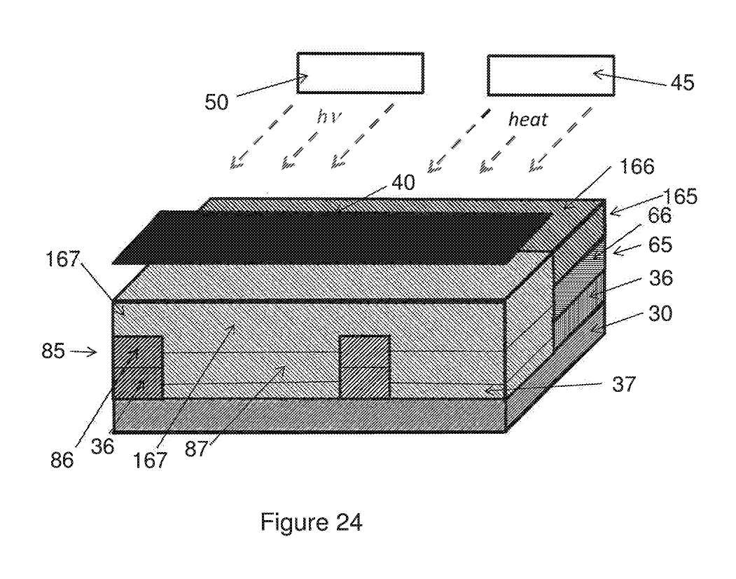

Next, as shown in FIG. 24, the method further comprises applying a curing condition to a target portion of the intermixed layer 160, without applying the curing condition to a non-target portion of the intermixed layer 160, to form an intermixed contrast layer 165 including at least one cured portion 166 and at least one uncured portion 167. For purposes of clarity, the at least one cured portion 166 may be referred to herein merely as “the cured portion,” and the at least one uncured portion 167 may be referred to herein merely as “the uncured portion,” and this terminology encompasses embodiments where the intermixed contrast layer 165 includes more than one cured portion 166 and/or more than one uncured portion 167, respectively.

Similar to curing of layers as described above, the method by which the intermixed layer 160 is selectively cured, and thus the curing condition utilized, is determined by at least the third composition for forming the intermixed layer 160 and the composition of the uncured portion 67 of the second contrast layer 65 which form the intermixed layer 160. For example, in certain embodiments, the intermixed layer 160 formed is curable upon exposure to active-energy rays from the source 50, i.e., the intermixed layer 160 is selectively cured by selectively irradiating the third layer with active-energy rays. The active-energy rays, similar to above, may comprise ultraviolet rays, electron beams, or other electromagnetic waves or radiation. Typically, the curing of the target portion of the intermixed layer 160 is by the same method as the curing any layer as described above. Alternatively, the intermixed layer 160 may be cured by thermal radiation through the use of a heating element 45, as also described above. In conjunction therewith, one or more photo or thermal masks 40 may also be utilized which are aligned with the respective target and non-target portions as described above.

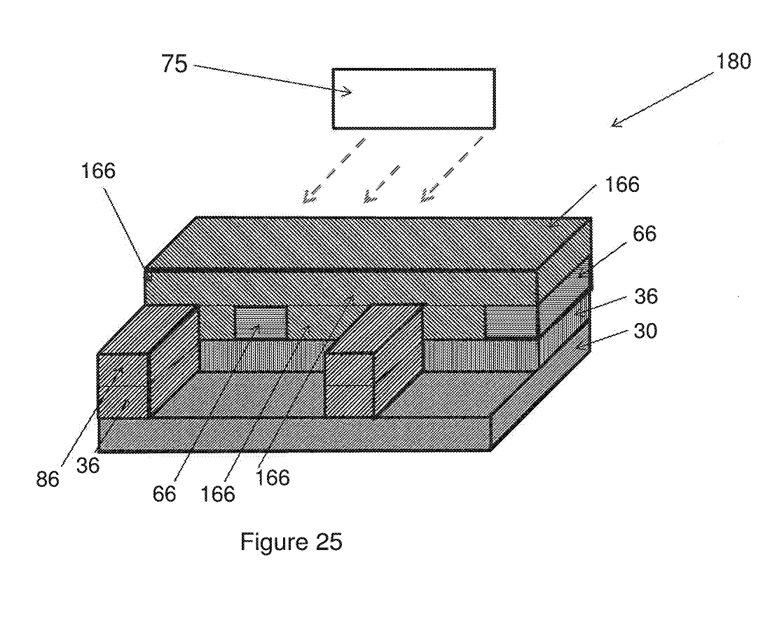

Next, as shown in FIG. 25, and similar to the selective removal steps illustrated in FIGS. 5 and 11 and 21 and described above, the method of this fourth embodiment further includes the step of selectively removing the uncured portions 37, 87, 167 of the first contrast layer 35, the intermixed contrast layer 85, and the intermixed contrast layer 165 therein forming the article 180. In certain embodiments, the uncured portions 37, 87, and 167 are selectively removed in a single step at the same time (i.e., selectively and simultaneously). However, in alternative embodiments, the selective removal may be sequential (i.e., wherein the uncured portion 167 is removed followed by the uncured portion 87 and uncured portion 37, or vice versa, in a single removal step after each of the uncured portions 37, 87, and 167 of the first contrast layer 35, the intermixed contrast layer 85, and the intermixed contrast layer 165 have been formed).

In certain embodiments, the article 180 is developed wherein the multiple applied layers 35, 85, 165 are soaked in a solvent, such as mesitylene or diethylene glycol monoethyl ether acetate, for a sufficient period of time such that the uncured portions 37, 87, and 167 begin to dissolve into the solvent 75. For example, in certain embodiments, multiple applied layers 35, 85, 165 are soaked for about 2 to 5 minutes. The multiple applied layers 35, 85, 165 are then rinsed with the same solvent, or another solvent in which the uncured portions 37, 87, and 167 are soluble, thus resulting in the removal of the uncured portions 37, 87, and 167, such that the article 180 remains. In addition, in certain embodiments, an optional post-bake may be utilized, wherein the article 180 is heated to a temperature sufficient to remove any residual solvent.

The resultant article 180, in any embodiment above, sequentially comprises the substrate 30, the first contrast layer 35 having the at least one cured portion 36 and not having the at least one uncured portion 37, the intermixed contrast layer 85 having the at least one cured portion 86 and not having the at least one uncured portion 87, and the intermixed contrast layer 165 having the at least one cured portion 166 and not having the at least one uncured portion 167.

In any of the above embodiments wherein an intermixed portion is formed (i.e., when layers intermix), the subsequently applied composition is generally miscible with the previously applied composition to allow for the formation of the intermixed portion (for example, wherein the second layer 60 is generally miscible in the uncured portion 37 of the second composition, the intermixed layer 80 may be formed, as described above previously with respect to FIG. 9). When these compositions are fully miscible with and in each other, the intermixed portion may be characterized as a homogenous blend. Alternatively, when these compositions are not fully miscible with or in each other or are incompletely mixed, the mixing of these compositions may form a non-homogenous intermixed portion. Alternatively, the intermixed portion may be partially homogenous. Typically, the intermixed portion is a homogeneous blend.

In addition, in any of the embodiments above, a portion, or the entirety, of any one cured portion of any layer may be aligned, or not aligned, to the adjacent cured portion of the next layer. For example, as shown in FIG. 5, some cured portion 36 of the first contrast layer 35 are aligned with the corresponding cured portion 66 of the second contrast layer 65 (shown wherein the cured portion 66 is stacked on top of the cured portion 36 at the front of FIG. 5), while other portions are not aligned (shown wherein a portion of the cured portion 36 of the first contrast layer 35 does not include a stacked cured portion 66 rearward in FIG. 5). Similarly, in FIG. 25, a portion of the cured portion 86 of intermixed layer 85 is not aligned to the cured portion of the intermixed contrast portion 165 at the front of FIG. 25 but is aligned to the cured portion 166 rearward in FIG. 25.

In certain embodiments, the first and second and third compositions each include a cationic polymerizable material including at least one cationic polymerizable group. Cationic polymerizable materials are typically curable upon exposure to active-energy rays via a cationic reaction mechanism. The cationic polymerizable group may be a neutral moiety. That is, the term “cationic” modifies polymerizable rather than group. The cationic polymerizable group may be located at any position(s) of the cationic polymerizable material. For example, the cationic polymerizable group may be pendent from or a substituent of the cationic polymerizable compound. The at least one cationic polymerizable group is referred to herein merely as “the cationic polymerizable group,” which, although singular, encompasses embodiments in which the cationic polymerizable group includes more than one cationic polymerizable group, i.e., two or more cationic polymerizable groups. Typically, the cationic polymerizable material includes two or more cationic polymerizable groups, which are independently selected.

In certain embodiments, the cationic polymerizable group comprises a heterocyclic functional group, defined as a cyclic organic functional group including at least one heteroatom, such as S, N, O, and/or P; alternatively S, N, and/or 0. For example, heterocyclic groups include, but are not limited to, lactone groups, lactam groups, cyclic ethers, and cyclic amines. Lactone groups are generally cyclic esters and may be selected from, for example, an acetolactone, a propiolactone, a butyrolactone, and a valerolactone. Lactam groups are generally cyclic amides and may be selected from, for example, a β-lactam, a γ-lactam, a δ-lactam and an ∈-lactam. Specific examples of cyclic ethers include oxirane, oxetane, tetrahydrofuran, and dioxepane (e.g. 1,3-dioxepane). Additional examples of heterocyclic functional groups include thietane and oxazoline. Notably, the heterocyclic functional groups described above may also exist as monomers. However, in the context of the cationic polymerizable group, the heterocyclic functional groups set forth above are substituents of a larger molecule and not discrete monomers. Further, these groups may be bonded or connected to the cationic polymerizable material via a divalent linking group.

In other embodiments, the cationic polymerizable group may comprise a cationic polymerizable group other than a heterocyclic functional group. For example, the cationic polymerizable group may alternatively be selected from an ethylenically unsaturated group, such as a vinyl, a vinyl ether, a divinyl ether, a vinyl ester, a diene, a tertiary vinyl, a styrene, or a styrene-derivative group.

Combinations of different heterocyclic functional groups, or combinations of cationic polymerizable groups other than heterocyclic functional groups, or combinations of heterocyclic functional groups and cationic polymerizable groups other than heterocyclic functional groups, may be included in the cationic polymerizable material.

In certain embodiments in which the cationic polymerizable material is organic, the first and/or second compositions may independently comprise an olefinic or polyolefinic material. In other embodiments, the first and/or second compositions comprise an organic epoxy-functional material, such as an epoxy resin. Specific examples of epoxy resins include bisphenol-type epoxy resins, such as bisphenol-A type, bisphenol-F type, bisphenol-AD type, bisphenol-S type, and hydrogenated bisphenol-A type epoxy resin; a naphthalene-type epoxy resin; a phenol-novolac-type epoxy resin; a biphenyl-type epoxy resin; a glycidylamine-type epoxy resin; an alicyclic-type epoxy resin; or a dicyclopentadiene-type epoxy resin. These epoxy resins can be used in combinations of two or more in each of the first and/or second compositions. Alternatively still, the first and/or second compositions may independently comprise a polyacrylic, a polyamide, a polyester, etc. or other organic polymeric material including the cationic polymerizable group. In these embodiments, the first and/or second compositions each independently comprise organic compositions. “Organic material,” as used herein, is distinguished from a silicone material, with silicone materials having a backbone comprising siloxane bonds (Si—O—Si) and organic materials having a carbon-based backbone and lacking siloxane bonds.

In other embodiments, for increasing miscibility, the first and second and third compositions each independently comprise a silicone composition or an organic composition.

When the first and/or second and/or third compositions comprise silicone compositions, the first and/or second and/or third compositions comprise a silicone material. The silicone composition and the silicone material comprise organopolysiloxane macromolecules, wherein each macromolecule independently may be straight or branched. The silicone material may comprise any combination of siloxane units, i.e., the silicone material comprise any combination of R₃SiO_{1/2} units, i.e., M units, R₂SiO_{2/2} units, i.e., D units, RSiO_{3/2} units, i.e., T units, and SiO_{4/2} units, i.e., Q units, where R is typically independently selected from a substituted or unsubstituted hydrocarbyl group or cationic polymerizable group. For example, R may be aliphatic, aromatic, cyclic, alicyclic, etc. Further, R may include ethylenic unsaturation. By “substituted,” it is meant that one or more hydrogen atoms of the hydrocarbyl may be replaced with atoms other than hydrogen (e.g. a halogen atom, such as chlorine, fluorine, bromine, etc.), or a carbon atom within the chain of R may be replaced with an atom other than carbon, i.e., R may include one or more heteroatoms within the chain, such as oxygen, sulfur, nitrogen, etc. R typically has from 1 to 10 carbon atoms. For example, R may have from 1 to 6 carbon atoms when aliphatic, or from 6 to 10 carbon atoms when aromatic. Substituted or unsubstituted hydrocarbyl groups containing at least 3 carbon atoms can have a branched or unbranched structure. Examples of hydrocarbyl groups represented by R include, but are not limited to, alkyl, such as methyl, ethyl, propyl, butyl, hexyl, heptyl, octyl, nonyl, decyl, and isomers of such groups; alkenyl, such as vinyl, allyl, and hexenyl; cycloalkyl, such as cyclopentyl, cyclohexyl, and methylcyclohexyl; aryl, such as phenyl and naphthyl; alkaryl, such as tolyl and xylyl; and aralkyl, such as benzyl and phenethyl. Examples of halogen-substituted hydrocarbyl groups represented by R are exemplified by 3,3,3-trifluoropropyl, 3-chloropropyl, chlorophenyl, dichlorophenyl, 2,2,2-trifluoroethyl, 2,2,3,3-tetrafluoropropyl, and 2,2,3,3,4,4,5,5-octafluoropentyl. Examples of the cationic polymerizable group represented by R are set forth above.

In embodiments in which the silicone material is resinous, the silicone material may comprise a DT resin, an MT resin, an MDT resin, a DTQ resin, an MTQ resin, an MDTQ resin, a DQ resin, an MQ resin, a DTQ resin, an MTQ resin, or an MDQ resin. Combinations of different resins may be present in the silicone material. Moreover, the silicone material may comprise a resin in combination with a polymer.

In one specific embodiment, the silicone material comprises or consists of an organopolysiloxane resin. The organopolysiloxane resin may be represented by the following siloxane unit formula:

(R¹R²R³SiO_{1/2})ₐ(R⁴R⁶SiO_{2/2})_{b}(R⁶SiO_{3/2})_{c}(SiO_{4/2})_{d},

where R¹, R², R³, R⁴, R⁵, and R⁶ are independently selected from R, which is defined above; a+b+c+d=1; “a” on average satisfies the following condition: 0≦a<0.4; “b” on average satisfies the following condition: 0<b<1; “c” on average satisfies the following condition: 0<c<1; “d” on average satisfies the following condition; 0≦d<0.4; and “b” and “c” are bound by the following condition: 0.01≦b/c≦0.3. Subscripts a, b, c, and d designate an average mole number of each siloxane unit. Said differently, these subscripts represent an average mole % or share of each siloxane unit in one molecule of the organopolysiloxane resin. Because R¹⁻⁶ are independently selected from R, the siloxane unit formula above can be rewritten as follows:

(R₃SiO_{1/2})ₐ(R₂SiO_{2/2})_{b}(RSiO_{3/2})_{c}(SiO_{4/2})_{d},

where R is independently selected and defined above, and a-d are defined above.

Typically, in one molecule of the organopolysiloxane resin, siloxane units including a cationic polymerizable group constitute 2 to 50 mole % of total siloxane units. Further, in these embodiments, at least 15 mole % of all silicon-bonded organic groups comprise univalent aromatic hydrocarbon groups with 6 to 10 carbon atoms (e.g. aryl groups).

The organopolysiloxane resin contains (R⁴R⁵SiO_{2/2}) and (R⁶SiO_{3/2}) as indispensable units. However, the organopolysiloxane may additionally comprise structural units (R¹R²R³SiO_{1/2}) and (SiO_{4/2}). In other words, the epoxy-containing organopolysiloxane resin may be composed of the units shown in the following formulae:

(R⁴R⁵Si^{O}_{2/2})_{b}(R⁶SiO_{3/2})_{c};

(R¹R²R³Si^{O}_{1/2})ₐ(R⁴R⁵SiO_{2/2})_{b}(R⁶SiO_{3/2})_{c};

(R⁴R⁵Si^{O}_{2/2})_{b}(R⁶SiO_{3/2})_{c}(SiO_{4/2})_{d}; or

(R¹R²R³Si^{O}_{1/2})ₐ(R⁴R⁵Si^{O}_{2/2})_{b}(R⁶SiO_{3/2})_{c}(SiO_{4/2})_{d}.

If the content of the (R¹R²R³SiO_{1/2}) units is too high, the molecular weight of the organopolysiloxane resin is reduced, and the following condition takes place: 0≦a<0.4. If (SiO_{4/2}) units are introduced under this condition, a cured product of the organopolysiloxane resin may become undesirably hard and brittle. Therefore, in certain embodiments, the following condition is met: 0≦d<0.4; alternatively 0≦d<0.2; alternatively d=0. The mole ratio b/c of the indispensable structural units (R⁴R⁶SiO_{2/2}) and (R⁶SiO_{3/2}) should be from 0.01 to 0.3, alternatively from 0.01 to 0.25, alternatively from 0.02 to 0.25. Because the organopolysiloxane resin contains (R⁴R⁶SiO_{2/2}) and (R⁶SiO_{3/2}) as indispensable units, the molecular structure may vary mainly between branched, net-like and three-dimensional.

The refractive index of the first and second and third compositions, when the first and second and third compositions each comprise the organopolysiloxane resin, may be selectively modified by changing the R groups of the respective organopolysiloxane resin. For example, when a majority of R groups in the organopolysiloxane resin are univalent aliphatic hydrocarbon groups, such as methyl groups, the refractive index of the organopolysiloxane resin may be less than 1.5. Alternatively, if a majority of the R groups in the organopolysiloxane resin are univalent aromatic hydrocarbon groups, such as phenyl groups, the refractive index may be greater than 1.5. This value can be readily controlled by substitution of the organopolysiloxane resin, or by inclusion of additional components in the first and/or second and/or third compositions, as described below.

In various embodiments of the organopolysiloxane resin, siloxane units having a cationic polymerizable group constitute from 2 to 70, alternatively from 10 to 40, alternatively 15 to 40, mole % of all siloxane units. If such siloxane units are present in the organopolysiloxane resin in an amount below 2 mole %, this will lead to a decrease in a degree of cross-linking during curing, which decreases hardness of the cured product formed therefrom. If, on the other hand, the content of these siloxane units exceeds 70 mole % in the organopolysiloxane resin, the cured product may have reduced visible light transmittance, low resistance to heat, and increased brittleness. Typically, the cationic polymerizable groups are not directly bonded to silicon atoms of the organopolysiloxane resin. Instead, the cationic polymerizable groups are generally bonded to silicon atoms via a bivalent linking group, such as a hydrocarbylene, heterohydrocarbylene, or organoheterylene linking group.

For example, when the cationic polymerizable groups are cyclic ether groups, e.g. epoxy groups, specific examples of cationic polymerizable groups suitable for the organopolysiloxane resin are set forth immediately below:

### 3-(glycidoxy) propyl group

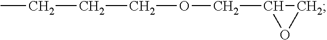

### 2-(glycidoxycarbonyl) propyl group

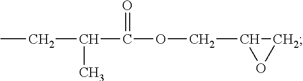

### 2-(3,4-epoxycyclohexyl) ethyl group

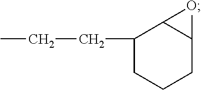

and

### 2-(4-methyl-3,4-epoxycyclohexyl) propyl group

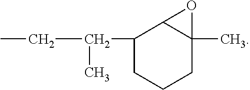

Additional examples of cyclic ether groups suitable for the cationic polymerizable group include the following: 2-glycidoxyethyl, 4-glycidoxybutyl, or similar glycidoxyalkyl groups; 3-(3,4-epoxycyclohexyl) propyl, or similar 3,4-epoxycyclohexylalkyl groups; 4-oxiranylbutyl, 8-oxiranyloctyl, or similar oxiranylalkyl groups. In these embodiments, the cationic polymerizable material may be referred to as an epoxy-functional silicone material.

Specific examples of cationic polymerizable groups other than the epoxy groups exemplified above include, but are not limited to, the following groups (with the left-most portion representing the bond connecting the particular cationic polymerizable group to the organopolysiloxane resin):

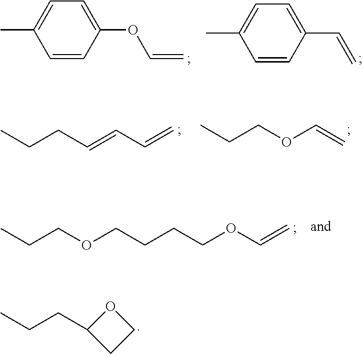

Specific examples of the organopolysiloxane resin when the cationic polymerizable groups are cyclic ether groups, e.g. epoxy groups, include organopolysiloxane resins comprising or consisting of the following sets of siloxane units: (Me₂SiO_{2/2}), (PhSiO_{3/2}), and (E¹SiO_{3/2}) units; (Me₃SiO_{1/2}), (Me₂SiO_{3/2}), (PhSiO_{3/2}), and (E¹SiO_{3/2}) units; (Me₂SiO_{2/2}), (PhSiO_{3/2}), (E¹SiO_{3/2}) and (SiO_{4/2}) units; (Me₂SiO_{2/2}), (PhSiO_{3/2}), (MeSiO_{3/2}), and (E¹SiO_{3/2}) units; (Ph₂SiO_{2/2}), (PhSiO_{3/2}), and (E¹SiO_{3/2}) units; (MePhSiO_{2/2}), (PhSiO_{3/2}), and (E¹SiO_{3/2}) units; (Me₂SiO_{2/2}), (PhSiO_{3/2}), and (E²SiO_{3/2}) units; (Me₂SiO_{2/2}), (PhSiO_{3/2}), and (E³SiO_{3/2}) units; (Me₂SiO_{2/2}), (PhSiO_{3/2}), and (E⁴SiO_{3/2}) units; (MeViSiO_{2/2}), PhSiO_{3/2}), and (E³SiO_{3/2}) units; (Me₂SiO_{2/2}), (PhSiO_{3/2}), (MeSiO_{3/2}), and (E³SiO_{3/2}) units; (Ph₂SiO_{2/2}), (PhSiO_{3/2}), and (E³SiO_{3/2}) units; (Me₂SiO_{2/2}), (Ph₂SiO_{2/2}), and (E¹SiO_{3/2}) units; (Me₂SiO_{2/2}), (Ph₂SiO_{2/2}), and (E³SiO_{3/2}) units; (Me₂ViSiO_{1/2}), (Me₂SiO_{2/2}), (PhSiO_{3/2}), and (E¹SiO_{3/2}) units; (Me₃SiO_{1/2}), (Ph₂SiO_{2/2}), (PhSiO_{3/2}), and (E¹SiO_{3/2}) units; (Me₃SiO_{1/2}), (Me₂SiO_{2/2}), (PhSiO_{3/2}), and (E³SiO_{3/2}) units; (Me₂SiO_{2/2}), (PhSiO_{3/2}), (E³SiO_{3/2}), and (SiO₂) units; (Me₂SiO_{2/2}), (Ph₂SiO_{2/2}), (E¹SiO_{3/2}), and (SiO₂) units; (Me₃SiO_{1/2}), (Me₂SiO_{2/2}), (PhSiO_{3/2}), (E¹SiO_{3/2}), and (SiO₂) units; and (Me₃SiO_{1/2}), (Me₂SiO_{2/2}), (PhSiO_{3/2}), (E³SiO_{3/2}), and (SiO₂) units; where Me designates a methyl group, Vi designates a vinyl group, Ph designates a phenyl group, E¹ designates a 3-(glycidoxy)propyl group, E² designates a 2-(glycidoxycarbonyl)propyl group, E³ designates a 2-(3,4-epoxycyclohexyl)ethyl group, and E⁴ designates 2-(4-methyl-3,4-epoxycyclohexyl) propyl group. The same designations are applicable to the following description herein. It is contemplated that any of the univalent hydrocarbon substituents exemplified in the organopolysiloxane resins above (e.g. Me, Ph, and Vi) may be replaced by other univalent hydrocarbon substituents. For example, an ethyl group or other substituted or unsubstituted hydrocarbyl group may be utilized in place of any of the methyl, phenyl, or vinyl groups above. Further, cationic polymerizable groups other than E¹-E⁴ may be utilized in place of or in addition to E¹-E⁴. However, the species of organopolysiloxane resin identified above are particularly desirable due to their refractive index values and physical properties.

The organopolysiloxane resin may have some residual silicon-bonded alkoxy groups and/or silicon-bonded hydroxyl groups (i.e., silanol groups) from its preparation. The content of these groups may depend on the method according to manufacture and manufacturing conditions. These substituents may affect storage stability of the organopolysiloxane resin and reduce thermal stability of the cured product formed from the organopolysiloxane resin. Therefore, in certain embodiments, it is desirable to restrict the formation of such groups. For example, the amount of silicon-bonded alkoxy groups and silicon-bonded hydroxyl groups can be reduced by heating the organopolysiloxane resin in the presence of a minute quantity of potassium hydroxide, thus causing a dehydration and condensation reaction or a de-alcoholation and condensation reaction. It is recommended that the content of these substituents be no more than 2 mole % and preferably no more than 1 mole % of all substituents on silicon atoms.

Although there are no special restrictions with regard to the number-average molecular weight (Mₙ) of the organopolysiloxane resin, the organopolysiloxane resin has, in certain embodiments, a Mₙ between 10³ and 10⁶ Daltons.

In certain embodiments, the first and/or second compositions and/or third compositions may not, alternatively may, further comprise a diluent component. In certain embodiments, the diluent component comprises a silane compound having a single (only one) silicon-bonded cationic polymerizable group.

The single silicon-bonded cationic polymerizable group may be any of the cationic polymerizable groups described above.

The silane compound generally has a dynamic viscosity of less than 1,000, alternatively less than 500, alternatively less than 100, alternatively less than 50, alternatively less than 25, alternatively less than 10, centipoise (cP) at 25° C. Dynamic viscosity may be measured with a Brookfield Viscometer, an Ubbelohde tube, cone/plate rheology, or other apparatuses and methods. Although the values may vary slightly based on the instrument/apparatus utilized, these values are generally maintained regardless of measurement type. In these embodiments, the silane compound has a boiling point temperature of at least 25, alternatively at least 50, alternatively at least 75, alternatively at least 80, alternatively at least 85, alternatively at least 90, ° C. at a pressure of 1 mm Hg (133.32 Pascals). For example, in certain embodiments, the silane compound has a boiling point temperature of from 80 to 120, alternatively from 90 to 110, ° C. at a pressure of 1 mm Hg.

In certain embodiments, the silane compound of the diluent component is free from any silicon-bonded hydrolysable groups other than potentially the cationic polymerizable group. For example, certain silicon-bonded hydrolysable groups, such as silicon-bonded halogen atoms, react with water to form silanol (SiOH) groups, wherein the silicon-halogen bond has been cleaved. Other silicon-bonded hydrolysable groups, such as a carboxylic ester, may hydrolyze without cleaving any bond to silicon. To this end, in certain embodiments, the silane compound is free from any silicon-bonded hydrolysable groups that may hydrolyze to form silanol groups. In other embodiments, the cationic polymerizable group of the silane compound is not hydrolysable such that the silane compound is free from any silicon-bonded hydrolysable groups altogether. In these embodiments, the cationic polymerizable group is not hydrolysable, e.g. the cationic polymerizable group is a cyclic ether. Specific examples of hydrolysable groups include the following silicon-bonded groups: a halide group, an alkoxy group, an alkylamino group, a carboxy group, an alkyliminoxy group, an alkenyloxy group, and an N-alkylamido group. For example, certain conventional silane compounds may have, in addition to more than one cationic polymerizable group, a silicon-bonded alkoxy group. Such silicon-bonded alkoxy groups of these conventional silane compounds may hydrolyse and condense, forming siloxane bonds and increasing a cross-link density of the cured product. In contrast, the silane compound is generally utilized to reduce a cross-link density of the cured product, and thus these hydrolysable groups are, in certain embodiments, undesirable.

In various embodiments, the silane compound of the diluent component has the following general formula:

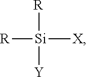

where R is independently selected and defined above, Y is the cationic polymerizable group, and X is selected from R and SiR₃.

In certain embodiments, X is R such that the silane compound comprises a monosilane compound. In these embodiments, the silane compound has the general formula YSiR₃, where Y and R are defined above. When Y is independently selected from E¹-E⁴ above, the silane compound may be rewritten as, for example, E¹SiR₃, E²SiR₃, E³SiR₃, and E⁴SiR₃. Of E¹-E⁴, E³ is most typical.

In other embodiments, X is SiR₃ such that the silane compound comprises a disilane compound. In these embodiments, the single cationic polymerizable group may be bonded to either silicon atom of the disilane, which silicon atoms are typically directly bonded to one another. Although R is independently selected from substituted and unsubstituted hydrocarbyl groups, R is most typically selected from alkyl groups and aryl groups for controlling the refractive index.

Specific examples of the silane compound and methods of their preparation are described in co-pending Application Ser. No. 61/824,424, which is incorporated by reference herein in its entirety.

The silane compound may effectively solubilize the cationic polymerizable material, e.g. the organopolysiloxane resin, thus obviating the need for another solvent. In some embodiments, the first and/or second compositions lack a solvent other than the silane compound. The silane compound also reduces the refractive index of first and/or second compositions, if present therein, and thus the relative amount of the silane compound utilized may be modified to selectively control the refractive index of the first and/or second compositions. For example, the first composition may utilize the silane compound in a lesser amount than the second composition, thereby imparting the second composition with a lesser refractive index than the first composition, all else being equal (e.g. the particular organopolysiloxane resin utilized).

The diluent component typically comprises the silane compound in an amount based on the desired refractive index and other physical properties of the first and/or second compositions. For example, in certain embodiments, the diluent component comprises the silane compound in an amount sufficient to provide at least 3, alternatively at least 5, alternatively at least 10, alternatively at least 15, alternatively at least 20, alternatively at least 25, alternatively at least 30, percent by weight of the silane compound based on the total weight of the second composition. The silane compound is generally present in a lesser amount in the first composition than in the second composition, if utilized in both.

The diluent component may not, alternatively may, comprise compounds or components in addition to the silane compound. For example, the diluent component may comprise a diluent compound other than and in addition to the silane compound. The diluent compound may differ from the silane compound in various respects. For example, the diluent compound may have more than one cationic polymerizable group. Alternatively, the diluent compound may have a single cationic polymerizable group, but may be free from silicon. The diluent component may comprise more than one diluent compound, i.e., the diluent component may comprise any combination of diluent compounds. The diluent compound may be aromatic, alicyclic, aliphatic, etc.

Specific examples of aromatic diluent compounds suitable for the diluent component include polyglycidyl ethers of polyhydric phenols each having at least one aromatic ring, or of alkylene oxide adducts of the phenols such as glycidyl ethers of bisphenol A and bisphenol F, or of compounds obtained by further adding alkylene oxides to bisphenol A and bisphenol F; and epoxy novolak resins.

Specific examples of alicyclic diluent compounds suitable for the diluent component include polyglycidyl ethers of polyhydric alcohols each having at least one alicyclic ring; and cyclohexene oxide- or cyclopentene oxide-containing compounds obtained by epoxidizing cyclohexene ring- or cyclopentene ring-containing compounds with oxidants. Examples include a hydrogenated bisphenol A glycidyl ether, 2-(3,4-epoxycyclohexyl-5,5-spiro-3,4-epoxy)cyclohexane-methadioxane, bis(3,4-epoxycyclohexylmethyl)adipate, vinylcyclohexene dioxide, 4-vinylepoxycyclohexane, bis(3,4-epoxy-6-methylcyclohexylmethyl)adipate, 3,4-epoxy-6-methylcyclohexylcarboxylate, dicyclopentadienediepoxide, ethyleneglycol di(3,4-epoxycyclohexylmethyl)ether, dioctyl epoxyhexahydrophthalate and di-2-ethylhexyl epoxyhexahydrophthalate.

Specific examples of aliphatic diluent compounds suitable for the diluent component include polyglycidyl ethers of aliphatic polyhydric alcohols and the alkyleneoxide adducts of the aliphatic polyhydric alcohols; polyglycidyl esters of aliphatic long-chain polybasic acid, homopolymers synthesized by the vinyl polymerization of glycidyl acrylate or glycidyl methacrylate, and copolymers synthesized by the vinyl polymerization of glycidyl acrylate and another vinyl polymer. Representative compounds include glycidyl ethers of polyhydric alcohols, such as 1,4-butanediol diglycidyl ether, 1,6-hexanediol diglycidyl ether, triglycidyl ethers of glycerine, triglycidyl ethers of trimethylolpropane, tetraglycidyl ethers of sorbitol, hexaglycidyl ethers of dipentaerythritol, diglycidyl ethers of polyethylene glycol, diglycidyl ethers of polypropyleneglycol, polyglycidyl ethers of polyether polyol obtained by adding one, two or more kinds of alkyleneoxides with an aliphaticpolyhydric alcohol such as propyleneglycol, trimethylol propane or glycerine, and diglycidyl esters of aliphatic long-chain dibasic acids. In addition, monoglycidyl ethers of aliphatic higher alcohols, phenol, cresol, butylphenol, monoglycidyl ethers of polyether alcohols obtained by adding alkyleneoxide to them, glycidyl esters of higher aliphatic acids, epoxidized soy-bean oil, octyl epoxystarate, butyl epoxystearate, epoxidized linseed oil, epoxidized polybutadiene, and the like are exemplified.

Additional examples of diluent compounds suitable for the diluent component include oxetane compounds, such as trimethylene oxide, 3,3-dimethyl oxetane and 3,3-dichloromethyl oxetane; trioxanes, such as tetrahydrofuran and 2,3-dimethyltetrahydrofuran; cyclic ether compounds, such as 1,3-dioxolane and 1,3,6-trioxacyclooctane; cyclic lactone compounds, such as propiolactone, butyrolactone and caprolactone; thiirane compounds, such as ethylene sulfide; thiethane compounds, such as trimethylene sulfide and 3,3-dimethylthiethane; cyclic thioether compounds, such as tetrahydrothiophene derivatives; spiro ortho ester compounds obtained by a reaction of an epoxy compound and lactone; and vinyl ether compounds such as ethyleneglycol divinyl ether, alkylvinyl ether, 3,4-dihydropyran-2-methyl(3,4-dihydropyran-2-methyl(3,4-dihydrpyra-ne-2-carboxylate) and triethyleneglycol divinyl ether.

If present, the diluent component typically comprises the diluent compound in an amount sufficient to provide from greater than 0 to 30, alternatively from greater than 0 to 10, alternatively from 1 to 5, percent by weight of the diluent compound based on the total weight of the first composition or the second composition, respectively. These values generally reflect any cationic polymerizable diluent compound other than the silane compound in the diluent component, i.e., when combinations of different diluent compounds are utilized, the values above represent their collective amounts. In certain embodiments, the diluent component comprises the silane compound and the diluent compound.

In certain embodiments, each of the first and second and third compositions further comprises a catalyst. The catalyst of the first composition may be the same as or different than the catalyst of the second composition, which may be the same or different from the catalyst of the third composition. Each catalyst independently is effective for enhancing curing of the respective composition. For example, when the first and second and third compositions are curable upon exposure to active-energy rays, the catalyst may be referred to as a photocatalyst. However, catalysts other than photocatalysts may be utilized, e.g. when the first and/or second compositions are cured upon exposure to heat as opposed to active-energy rays. The photocatalyst may alternatively be referred to as a photopolymerization initiator, and generally serves to initiation photopolymerization of the cationic polymerizable material and the diluent component. In certain embodiments, the first and second compositions independently comprise (A) an organopolysiloxane resin; and (B) a catalyst. The organopolysiloxane resin is described above. The catalyst may comprise any catalyst suitable for such polymerization. Examples of catalysts may include sulfonium salts, iodinium salts, selenonium salts, phosphonium salts, diazonium salts, paratoluene sulfonate, trichloromethyl-substituted triazine, and trichloromethyl-substituted benzene. Additional catalyst include acid generators, which are known in the art. The catalyst may increase rate of curing the composition, decrease time to onset of curing, increase extent of crosslinking of the composition, increase crosslink density of the cured product, or a combination of any two or more thereof. Typically, the catalyst at least increases the rate of curing the composition.

The sulfonium salts suitable for the catalyst may be expressed by the following formula: R⁷₃S⁺X⁻, where R⁷ may designated a methyl group, ethyl group, propyl group, butyl group, or a similar alkyl group with 1 to 6 carbon atoms; a phenyl group, naphthyl group, biphenyl group, tolyl group, propylphenyl group, decylphenyl group, dodecylphenyl group, or a similar aryl or a substituted-aryl group with 6 to 24 carbon atoms. In the above formula, X⁻ represents SbF₆⁻, AsF₆⁻, PF₆⁻, BF₄⁻, B(C₆F₅)₄⁻, HSO₄⁻, ClO₄⁻, CF₃SO₃⁻, or similar non-nucleophilic, non-basic anions. The iodonium salts can be represented by the following formula: R⁷₂l⁺X⁻, where R⁷ is the same as X⁻ defined above. The selenonium salt can be represented by the following formula: R⁷₃Se⁺X⁻, where R⁷, X⁻are the same as defined above. The phosphonium salt can be represented by the following formula: R⁷₄P⁺X⁻, wherein R⁷, X⁻are the same as defined above. The diazonium salt can be represented by the following formula: R⁷N₂⁺X⁻, where R⁷ and X⁻are the same as defined above. The para-toluene sulfonate can be represented by the following formula: CH₃C₆H₄SO₃R⁸, wherein R⁸ is an organic group that contains an electron-withdrawing group, such as a benzoylphenylmethyl group, or a phthalimide group. The trichloromethyl-substituted triazine can be represented by the following formula: [CCl₃]₂C₃N₃R⁹, wherein R⁹ is a phenyl group, substituted or unsubstituted phenylethynyl group, substituted or unsubstituted furanylethynyl group, or a similar electron-withdrawing group. The trichloromethyl-substituted benzene can be represented by the following formula: CCl₃C₆H₃R⁷R¹⁰, wherein R⁷ is the same as defined above, R¹⁰ is a halogen group, halogen-substituted alkyl group, or a similar halogen-containing group.

Specific examples of catalysts suitable for the first and/or second compositions include triphenylsulfonium tetrafluoroborate, triphenylsulfonium hexafluoroantimonate, triphenylsulfonium trifurate, tri(p-tolyl)sulfonium hexafluorophosphate, p-tertiarybutylphenyl diphenylsulfonium hexafluoroantimonate, diphenyliodonium tetrafluoroborate, diphenyliodonium hexafluoroantimonate, p-tertiarybutylphenyl biphenyliodonium hexafluoroantimonate, di(p-tertiarybutylphenyl) iodonium hexafluoroantimonate, bis(dodecylphenyl)iodonium hexafluoroantimonate, triphenylselenonium tetrafluoroborate, tetraphenylphosphonium tetrafluoroborate, tetraphenylphosphonium hexafluoroantimonate, p-chlorophenyldiazonium tetrafluoroborate, benzoylphenyl paratolyenesulfonate, bistrichloromethylphenyl triazine, bistrichloromethyl furanyltriazine, p-bistrichloromethyl benzene, etc.

The catalyst may comprise two or more different species, optionally in the presence of a carrier solvent.

The catalyst may be present in the first and second and third compositions in independently varying amounts. Generally, the catalyst is present in an amount sufficient to initiate polymerization and curing upon exposure to active-energy rays (i.e., high-energy rays), such as ultraviolet rays. In certain embodiments, the catalyst is utilized in each of the first and second compositions in an amount of from greater than 0 to 5, alternatively from 0.1 to 4, percent by weight based on the total weight of the respective composition.

The first and/or second and/or third compositions may be solventless. In these embodiments, the diluent component generally solubilizes the cationic polymerizable material sufficient to pour and wet coat the first and/or second compositions. However, if desired, the first and/or second compositions may further comprise a solvent, e.g. an organic solvent. Solventless, as used herein with reference to the first and/or second compositions being solventless, means that total solvent, including any carrier solvent, may be present in the respective composition in an amount of less than 5, alternatively less than 4, alternatively less than 3, alternatively less than 2, alternatively less than 1, alternatively less than 0.1, percent by weight based on the total weight of the respective composition.

The solvent, if utilized, is generally selected for miscibility with the cationic polymerizable material and the diluent component. Generally, the solvent has a boiling point temperature of from 80° C. to 200° C. at atmospheric pressure, which allows for the solvent to be easily removed via heat or other methods. Specific examples of solvents include, but are not limited to, isopropyl alcohol, tertiarybutyl alcohol, methylethyl ketone, methyl isobutyl ketone, toluene, xylene, mesitylene, chlorobenzene, ethylene glycol dimethyl ether, ethylene glycol diethyl ether, diethylene glycol dimethylether, ethoxy-2-propanolacetate, methoxy-2-propanolacetate, octamethylcyclotetrasiloxane, hexamethyldisiloxane, diethylene glycol monoethyl ether acetate, benzyl alcohol, 2-ethyl hexyl acetate, ethyl benzoate, 2-butoxy-ethoxy ethyl acetate, diethylene glycol butyl ether, diethylene glycol monoethyl ether acetate, and diethylene glycol butyl ether. Two or more solvents may be utilized in combination.

The first and/or second and/or third compositions may optionally and additionally include any other suitable component(s), such as a coupling agent, an antistatic agent, an ultraviolet absorber, a plasticizer, a leveling agent, a pigment, a catalyst, an inhibitor of the catalyst, and so on. The inhibitor of the catalyst may function to prevent or slow rate of curing until the catalyst is activated (e.g. by removing or deactivating the inhibitor).

In certain embodiments, the first and second and third compositions are each in the form of a liquid with a dynamic viscosity of from 20 to 10,000 mPa·s at 25° C. The dynamic viscosities may be measured with a Brookfield Viscometer, an Ubbelohde tube, cone/plate rheology, or other apparatuses and methods. Although the values may vary slightly based on the instrument/apparatus utilized, these values are generally maintained regardless of measurement type.

The method and articles 20, 90, 150, 180 of the invention are applicable for both passive-system elements and active-system elements. The following are examples of such applications: non-branched type optical waveguides, wave division multiplexers [WDM], branched optical waveguide, optical adhesives or similar passive light-transmitting elements, optical waveguide switches, optical attenuators, and optical amplifiers or similar active light-transmitting elements. Additional examples of suitable articles and applications in which the method and article may be utilized include volumetric phase gratings, Bragg gratings, Mach Zhender interferometers, lenses, amplifiers, cavities for lasers, acusto-optic devices, modulators, and dielectric mirrors.

The dimensions of the any respective layer of the respective articles 20, 90, 150, 180 may vary based on an intended end use of the respective articles 20, 90, 150, 180. When the respective article 20, 90, 150, 180 comprises an optical article, the thickness of the cured portion of the second contrast layer, which may alternatively be referred to as the core layer, is most relevant, with the thicknesses of other layers being not particularly important. The thickness of the cured portion of the core layer is typically from 1 to 100, alternatively from 1 to 60, alternatively from 20 to 40, micrometers (μm). The thicknesses of the other layers may independently vary, for example from 1 to 100 micrometers.

In certain embodiments, the formed articles 20, 90, 150, 180 in the present invention may be further processed to be coupled with one or more fiber connectors 200.

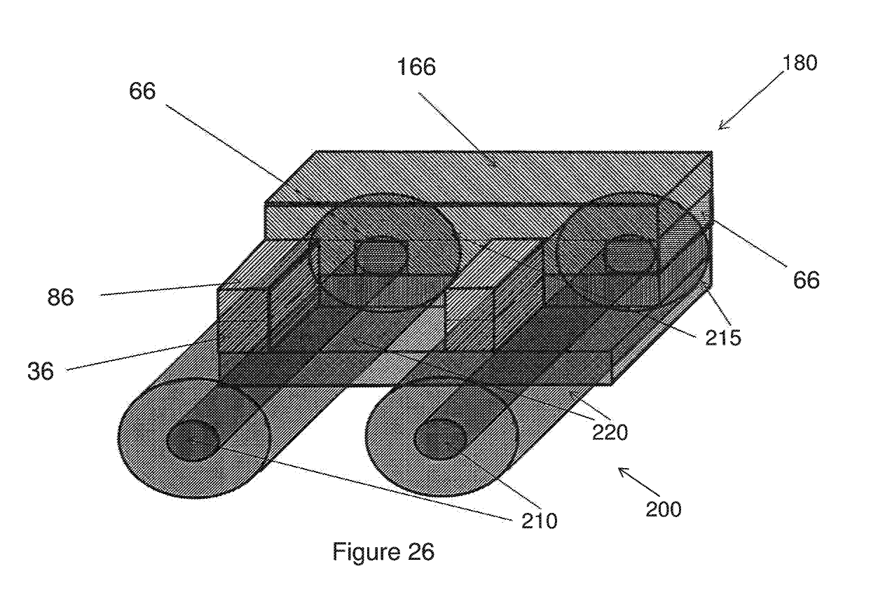

Referring now to FIG. 26, as representative of this further aspect, the article 180 formed in accordance with the method described above as illustrated in FIGS. 22-25 is coupled to a fiber connector 200 including an inner core 210 surrounded by an outer core 220.

Specifically, a first end 215 of the inner core 210 of a respective one of the fiber connectors 200 (here shown as two fiber connectors 200) is aligned with and contacted to a corresponding one of the at least one cured portion 66 (also referred to as the core) of the second contrast layer 65. The remaining outer layers 36 and 66 may also be described, such as in the Examples below, as the clad.

While the inner core 210 is generally shown as cylindrical in shape, with the first end 215 being circular in cross-section, other shapes are specifically contemplated although not illustrated. For example, the inner core 210 could be rectangular in shape, with the first end 215 square or rectangular in cross-section. Similarly, the relative size of the inner core 210 and corresponding first end 215 may be sized differently relative to the size of the at least one cured portion 66 to which it is coupled. Thus, for example, the size and shape of the first end 215 could be made to conform, or not conform, to the size and shape of the end of corresponding cured portion 66 to which it is aligned. Similarly, the relative size and shape of the outer core 210 relative to the inner core 215 is not limited to the size and shape drawn in FIG. 25.

The present invention thus provides a simple and repeatable method for forming articles, and their subsequent use with fiber connectors 200 and the like. The method of the present invention improves the process for forming these respective articles by forming the articles at a lesser cost and with fewer steps than conventional methods required to prepare similar articles. Notably, the removal of the uncured portions of first, second and third contrast layer (if present) after application of the each of the layers removes one or two (if the third contrast layer is present) removal steps from the process. Associated therewith, elimination of the step to remove uncured portions of the first contrast layer, prior to application of the second layer onto the first contrast layer, improves adhesion of the second layer (and subsequently the second contrast layer) to the first contrast layer. Similarly, elimination of the step to remove uncured portions of the second contrast layer, prior to application of the third layer onto the second contrast layer, improves adhesion of the third layer (and subsequently the third contrast layer) to the second contrast layer. This may result in a decrease in the failure rate in fabricating fully functional optical waveguides. The invention method is particularly suitable for preparing optical articles, such as waveguides, as noted above, and in particular for forming articles having stacked waveguides.

The appended claims are not limited to express and particular compounds, compositions, or methods described in the detailed description, which may vary between particular embodiments which fall within the scope of the appended claims. With respect to any Markush groups relied upon herein for describing particular features or aspects of various embodiments, different, special, and/or unexpected results may be obtained from each member of the respective Markush group independent from all other Markush members. Each member of a Markush group may be relied upon individually and or in combination and provides adequate support for specific embodiments within the scope of the appended claims.

Further, any ranges and subranges relied upon in describing various embodiments of the present invention independently and collectively fall within the scope of the appended claims, and are understood to describe and contemplate all ranges including whole and/or fractional values therein, even if such values are not expressly written herein. One of skill in the art readily recognizes that the enumerated ranges and subranges sufficiently describe and enable various embodiments of the present invention, and such ranges and subranges may be further delineated into relevant halves, thirds, quarters, fifths, and so on. As just one example, a range “of from 0.1 to 0.9” may be further delineated into a lower third, i.e., from 0.1 to 0.3, a middle third, i.e., from 0.4 to 0.6, and an upper third, i.e., from 0.7 to 0.9, which individually and collectively are within the scope of the appended claims, and may be relied upon individually and/or collectively and provide adequate support for specific embodiments within the scope of the appended claims. In addition, with respect to the language which defines or modifies a range, such as “at least,” “greater than,” “less than,” “no more than,” and the like, it is to be understood that such language includes subranges and/or an upper or lower limit. As another example, a range of “at least 10” inherently includes a subrange of from at least 10 to 35, a subrange of from at least 10 to 25, a subrange of from 25 to 35, and so on, and each subrange may be relied upon individually and/or collectively and provides adequate support for specific embodiments within the scope of the appended claims. Finally, an individual number within a disclosed range may be relied upon and provides adequate support for specific embodiments within the scope of the appended claims. For example, a range “of from 1 to 9” includes various individual integers, such as 3, as well as individual numbers including a decimal point (or fraction), such as 4.1, which may be relied upon and provide adequate support for specific embodiments within the scope of the appended claims.

Some embodiments include any one or more of the following numbered aspects.

Aspect 1. A method of preparing an article, said method comprising: applying a first composition having a first refractive index (RI¹) on a substrate to form a first layer comprising the first composition on the substrate; applying a curing condition to a target portion of the first layer, without applying the curing condition to a non-target portion of the first layer, to form a first contrast layer including at least one cured portion and at least one uncured portion; applying a second composition having a second refractive index (RI²) on the first contrast layer to form a second layer, the second refractive index (RI²) being the same or different from the first refractive index (RI¹); applying a curing condition to a target portion of the second layer, without applying the curing condition to a non-target portion of the second layer, to form a second contrast layer including at least one cured portion and at least one uncured portion; and selectively removing the at least one uncured portion of the first contrast layer and the at least one uncured portion of the second contrast layer to prepare the article, wherein the article sequentially comprises the substrate, the first contrast layer having the at least one cured portion and not having the at least one uncured portion, and the second contrast layer having the at least one cured portion and not having the at least one uncured portion.

Aspect 2. The method according to aspect 1 wherein the step of selectively removing the at least one uncured portion of the first contrast layer and the at least one uncured portion of the second contrast layer comprises simultaneously and selectively removing the at least one uncured portion of the first contrast layer and the at least one uncured portion of the second contrast layer.

Aspect 3. The method according to aspect 1 or 2 wherein applying a curing condition to the target portion of the first layer comprises irradiating the target portion of the first layer with active-energy rays without irradiating the non-target portion of the first layer with the active-energy rays.

Aspect 4. The method according to any preceding aspect wherein applying a curing condition to the target portion of the second layer comprises irradiating the target portion of the second layer with active-energy rays without irradiating the non-target portion of the second layer with the active-energy rays and without irradiating the non-target portion of the first contrast layer with the active-energy rays.

Aspect 5. The method according to any preceding aspect wherein the first and second compositions independently comprise: (A) an organopolysiloxane resin; and (B) a catalyst for enhancing curing of the organopolysiloxane resin.

Aspect 6. A method of preparing an article, said method comprising: applying a first composition having a first refractive index (RI¹) on a substrate to form a first layer comprising the first composition on the substrate; applying a curing condition to a target portion of the first layer, without applying the curing condition to a non-target portion of the first layer, to form a first contrast layer including at least one cured portion and at least one uncured portion; applying a second composition having a second refractive index (RI²) on the first contrast layer to form a second layer, the second refractive index (RI²) being the same or different from the first refractive index (RI¹); applying a curing condition to a target portion of the second layer, without applying the curing condition to a non-target portion of the second layer, to form a second contrast layer including at least one cured portion and at least one uncured portion; applying a third composition having a third refractive index (RI³) on the second contrast layer to form a third layer, the third refractive index (RI³) being the same or different than the second refractive index (RI²) and being the same or different from the first refractive index (RI¹); applying a curing condition to a target portion of the third layer, without applying the curing condition to a non-target portion of the third layer, to form a third contrast layer including at least one cured portion and at least one uncured portion; and selectively removing the at least one uncured portion of the first contrast layer and the at least one uncured portion of the second contrast layer and the at least one uncured portion of the third contrast layer to prepare the article, wherein the article sequentially comprises the substrate, the first contrast layer having the at least one cured portion and not having the at least one uncured portion, the second contrast layer having the at least one cured portion and not having the at least one uncured portion, and the third contrast layer having the at least one cured portion and not having the at least one uncured portion.

Aspect 7. The method according to aspect 6 wherein RI²>RI³ and wherein RI²>RI¹ when measured at a same wavelength of light and temperature.

Aspect 8. The method according to aspect 6 or 7 wherein RI³>RI¹ when measured at a same wavelength of light and temperature.

Aspect 9. The method according to aspect 6 or 7 wherein RI¹>RI³ when measured at a same wavelength of light and temperature.

Aspect 10. The method according to aspect 6 or 7 wherein RI¹=RI³ when measured at a same wavelength of light and temperature.

Aspect 11. The method according to aspect 6 wherein RI′=RI²=RI³ when measured at a same wavelength of light and temperature.

Aspect 12. The method according to any one of aspects 6 to 11 wherein the step of selectively removing the at least one uncured portion of the first contrast layer and the at least one uncured portion of the second contrast layer and the at least one uncured portion of the third contrast layer comprises simultaneously and selectively removing the at least one uncured portion of the first contrast layer and the at least one uncured portion of the second contrast layer and the at least one uncured portion of the third contrast layer.

Aspect 13. The method according to any one of aspects 6 to 12 wherein applying a curing condition to the target portion of the first layer comprises irradiating the target portion of the first layer with active-energy rays without irradiating the non-target portion of the first layer with the active-energy rays.

Aspect 14. The method according to any one of aspects 6 to 12 wherein applying a curing condition to the target portion of the second layer comprises irradiating the target portion of the second layer with active-energy rays without irradiating the non-target portion of the second layer with the active-energy rays and without irradiating the non-target portion of the first contrast layer with the active energy rays.

Aspect 15. The method according to any one of aspects 6 to 14 wherein applying a curing condition to the target portion of the third layer comprises irradiating the target portion of the third layer with active-energy rays without irradiating the non-target portion of the third layer with the active-energy rays and without irradiating the non-target portion of the second contrast layer with the active-energy rays and without irradiating the non-target portion of the first contrast layer with the active energy rays.

Aspect 16. The method according to any one of aspects 6 to 15 wherein the first and second and third compositions independently comprise: (A) an organopolysiloxane resin; and (B) a catalyst for enhancing curing of the organopolysiloxane resin.

Aspect 17. The method according to any one of aspects 6 to 16, wherein the second composition is mixed with at least a portion of the at least one uncured portion of the first contrast layer to form the second layer prior to the step of forming the second contrast layer.

Aspect 18. The method according to any one of aspects 6 to 17, wherein the third composition is mixed with at least a portion of the at least one uncured portion of the second contrast layer to form the third layer prior to the step of forming the third contrast layer.

Aspect 19. The method according to any one of aspects 6 to 17, wherein the third composition is mixed with at least a portion of the at least one uncured portion of the second contrast layer and at least a portion of the at least one uncured portion of the first contrast layer to form the third layer prior to the step of prior to the step of forming the third contrast layer.

Aspect 20. The method according to any one of aspects 6 to 19 wherein each one of the at least one uncured portion of the second contrast layer is aligned with and adjacent to a corresponding one of the at least one uncured portion of the first contrast layer and wherein each one of the at least one uncured portion of the third contrast layer is aligned with and adjacent to a corresponding one of the at least one uncured portion of the second contrast layer.

Aspect 21. The method according to any one of aspects 6 to 19 wherein at least a portion of one of the at least one uncured portion of the second contrast layer is not aligned with or adjacent to a corresponding one of the at least one uncured portion of the first contrast layer.

Aspect 22. The method according to any one of aspects 6 to 19 and 21 wherein at least a portion of one of the at least one uncured portion of the third contrast layer is not aligned with or adjacent to a corresponding one of the at least one uncured portion of the second contrast layer.

Aspect 23. An article prepared by the method according to any one of aspects 1 to 22.

The following examples are intended to illustrate the invention and are not to be viewed in any way as limiting to the scope of the invention.

### EXAMPLES

### Curable Silicone Composition 1

A curable silicone composition including dimethylvinyl terminated phenyl and 2-[3,4-epoxycyclohexyl]ethyl silsesquioxanes, dimethylphenyl 2-[3,4-epoxycyclohexyl]ethyl silane, and a commercially available photoacid generator.

### Curable Silicone Composition 2

A curable silicone composition including dimethylvinyl terminated phenyl and 2-[3,4-epoxycyclohexyl]ethyl silsesquioxane-polyphenylmethylsiloxane copolymer; dimethylphenyl 2-[3,4-epoxycyclohexyl]ethyl silane, and a commercially available photoacid generator.

### Curable Silicone Composition 3

A curable silicone composition including dimethylvinyl terminated phenyl and 2-[3,4-epoxycyclohexyl]ethyl silsesquioxanes, dimethylphenyl 2-[3,4-epoxycyclohexyl]ethyl silane, bis-[2-(3,4-epoxycyclohexyl)ethyl]tetramethyldisiloxane and a commercially available photoacid generator.

### Curable Silicone Composition 4

A curable silicone composition including phenyl and 2-[3,4-epoxycyclohexyl]ethyl silsesquioxanes, dimethylvinyl terminated, toluene, and a commercially available photoacid generator.

### Curable Silicone Composition 5

A curable silicone composition including phenyl and 2-[3,4-epoxycyclohexyl]ethyl silsesquioxane-phenylmethylsiloxane copolymer, dimethylphenyl 2-[3,4-epoxycyclohexyl]ethyl silane, cylohexanedimethanol diglycidyl ether, Bis((3,4-epoxycyclohexyl)methyl)adipate, and a commercially available photoacid generator.

### Example 1

A coating of Curable Silicone Composition 1 with a refractive index of 1.535 (was spin coated onto a silicon wafer at 1900 RPM for 60 seconds. The coated wafer was then placed on an EVG® 6200NT device (an automated mask alignment system for optical double sided lithography device commercially available from EV Group, Inc. of Albany, N.Y.) with a photo mask placed between the UV light source and the coating at a distance of 100 micron from the wafer. The coating was then selectively irradiated via the photo mask at a dose of 0.6 J/cm² and the regions exposed to the UV light cross linked and hardened whereas the areas which were protected by the photo mask remained uncured or soluble to solvents.

A coating of Curable Silicone Composition 2 with a refractive index of 1.515 was then coated on top of the first processed layer. The photo mask was then placed between the UV light source and the coating at a distance of 100 micron from the wafer. The photo mask was then aligned such that the vias in the first processed layer lines up with the vias openings on the photo mask. The second layer was then irradiated via the photo mask at a dose of 1.2 J/cm². The processed wafer is then soaked in Mesitylene for 2 minutes. The solvent then dissolves then uncured regions of the layer 1 and layer 2. The coatings are then rinsed with mesitylene for 10 sec, followed by a 15 sec rinse with isopropanol. The wafer is the spin dried at 1500 RPM to remove any residues. The resulting architecture consists of layers 1 and layers 2 which were patterned and developed using a single development step.

### Example 2

A coating of Curable Silicone Composition 3 with a refractive index of 1.505 was spin coated onto a silicon wafer at 1900 RPM for 60 sec. The coated wafer was then placed on the EVG® 6200NT device with a photo mask placed between the UV light source and the coating at a distance of 100 micron from the wafer. The coating is then selectively irradiated via the photo mask at 1.2 J/cm² and the region exposed to the UV light cross links and hardens whereas the areas which were protected by the photo mask remain uncured or soluble to solvents. This process form a patterned bottom clad layer.

A second coating of Curable Composition 1 with a refractive index of 1.535 was then coated on top of the first processed layer. The photo mask is then placed between the UV light source and the coating at a distance of 100 micron from the wafer. The photo mask is then aligned such that the vias in the first processed layer lines up with the vias openings on the photo mask. The second layer is then irradiated via the photo mask at a dose 0.25 J/cm². This process forms a patterned core on top of a patterned clad which. The processed wafer is then soaked in mesitylene for 2 minutes to dissolve the uncured regions of the bottom clad and core layer. The coatings are then rinsed with mesitylene for 10 sec, followed by a 15 sec rinse with iso-propanol. The wafer is the spin dried at 1500 RPM to remove any residues. The resulting architecture consists of patterned clad on a patterned core resulting in stacked polymer waveguide architecture.

### Example 3

A coating of Curable Silicone Composition 5 with a refractive index of 1.515 was spin coated onto a silicon wafer at 600 RPM for 60 sec. The coated wafer was then placed on the EVG® 6200NT device with a photo mask placed between the UV light source and the coating at a distance of 100 micron from the wafer. The coating was then selectively irradiated via the photo mask at 1.2 J/cm² and the regions exposed to the UV light cross linked and hardened whereas the areas which were protected by the photo mask remained uncured or soluble to solvents. This process formed a patterned bottom clad layer.

A second coating of Curable Silicone Composition 1 with a refractive index of 1.535 was then coated on top of the first processed layer at 1900 RPM for 30 seconds. The photo mask was then placed between the UV light source and the coating at a distance of 100 micron from the wafer. The photo mask was then aligned using the alignments marks on the bottom layer to form a stacked waveguide structure with slots for fiber connectors. The second layer was then irradiated via the photo mask at a dose 0.25 J/cm².

The processed wafer was then soaked in diethylene glycol monoethyl ether acetate (DGMEA) for 5 minutes to dissolve the uncured regions of the bottom clad and core layer. The coatings were then rinsed with DGMEA for 30 seconds, followed by a 1 min rinse with iso-propanol. The wafer was then spin dried at 1500 RPM for 30 seconds to remove any residues. The resulting architecture consisted of patterned clad on a patterned core resulting in a stacked polymer waveguide architecture.

A final layer of Curable Silicone Composition 5 with a refractive index of 1.515 was spin coated on top of the two layer stacked architecture at 600 RPM for 60 sec to form the top clad layer of the waveguide architecture. The coated wafer was then placed on the EVG 6200NT with a photo mask placed between the UV light source and the coating at a distance of 100 micron from the wafer. The coating was then selectively irradiated via the photo mask at 1.2 J/cm² and the regions exposed to the UV light cross linked and hardened whereas the areas which were protected by the photo mask remained uncured or soluble to solvents. The processed wafer was then solvent developed as described before to remove the uncured portions of the top clad layer.

### Example 4

A coating Curable Silicone Composition 5 with a refractive index of 1.505 was spin coated onto a silicon wafer at 1900 RPM for 30 seconds. The coated wafer was then placed on the EVG 6200NT device with a photo mask placed between the UV light source and the coating at a distance of 100 micron from the wafer. The coating was then selectively irradiated via the photo mask at 1.2 J/cm² and the regions exposed to the UV light cross linked and hardened whereas the areas which were protected by the photo mask remained uncured or soluble to solvents. This process formed a patterned bottom clad layer.

A second coating of Curable Silicone Composition 4 with a refractive index of 1.525 was then coated on top of the first processed layer at 800 RPM for 60 seconds. The photo mask was then placed between the UV light source and the coating at a distance of 100 micron from the wafer. The photo mask was then aligned using the alignments marks on the bottom layer to form a stacked waveguide structure with slots for fiber connectors. The second layer was then irradiated via the photo mask at a dose 0.8 J/cm² to form a patterned core on top of a patterned bottom clad.

A third coating of Curable Silicone Composition 3 was then coated on top of the stacked bottom clad-core combination. The third layer with a refractive index of 1.515 was spin coated at 600 RPM for 60 sec to form the top clad layer of the waveguide architecture. The coated wafer was then placed on the EVG 6200NT with a photo mask placed between the UV light source and the coating at a distance of 100 micron from the wafer. The coating was then selectively irradiated via the photo mask at 1.2 J/cm² and the regions exposed to the UV light cross linked and hardened whereas the areas which were protected by the photo mask remained uncured or soluble to solvents. The UV curing of the third layer resulted in the curing of the intermixed clad and core layers. The processed wafer with the stacked waveguide architecture was then soaked in diethylene glycol monoethyl ether acetate (DGMEA) for 5 minutes to dissolve the uncured regions of the bottom clad, core and top clad layer. The coatings were then rinsed with DGMEA for 30 seconds, followed by a 1 minute rinse with isopropanol. The wafer was then spin dried at 1500 RPM for 30 seconds to remove any residues. The resulting architecture consisted of an intermixed clad and core with a stacked architecture consisting of patterned bottom clad-patterned core-patterned top clad.

The invention has been described in an illustrative manner, and it is to be understood that the terminology which has been used is intended to be in the nature of words of description rather than of limitation. Obviously, many modifications and variations of the present invention are possible in light of the above teachings. The invention may be practiced otherwise than as specifically described. Calling an example a comparative example does not mean that it is prior art.

1. A method of preparing an article, said method comprising:
applying a first composition having a first refractive index (RI¹) on a substrate to form a first layer comprising the first composition on the substrate;
applying a curing condition to a target portion of the first layer, without applying the curing condition to a non-target portion of the first layer, to form a first contrast layer including at least one cured portion and at least one uncured portion;
applying a second composition having a second refractive index (RI²) on the first contrast layer to form a second layer, the second refractive index (RI²) being the same or different from the first refractive index (RI¹);
applying a curing condition to a target portion of the second layer, without applying the curing condition to a non-target portion of the second layer, to form a second contrast layer including at least one cured portion and at least one uncured portion; and
selectively removing the at least one uncured portion of the first contrast layer and the at least one uncured portion of the second contrast layer to prepare the article, wherein the article sequentially comprises the substrate, the first contrast layer having the at least one cured portion and not having the at least one uncured portion, and the second contrast layer having the at least one cured portion and not having the at least one uncured portion.

2. The method according to claim 1 wherein the step of selectively removing the at least one uncured portion of the first contrast layer and the at least one uncured portion of the second contrast layer comprises simultaneously and selectively removing the at least one uncured portion of the first contrast layer and the at least one uncured portion of the second contrast layer

3. The method according to claim 1 wherein applying a curing condition to the target portion of the first layer comprises irradiating the target portion of the first layer with active-energy rays without irradiating the non-target portion of the first layer with the active-energy rays.

4. The method according to claim 1 wherein applying a curing condition to the target portion of the second layer comprises irradiating the target portion of the second layer with active-energy rays without irradiating the non-target portion of the second layer with the active-energy rays and without irradiating the non-target portion of the first contrast layer with the active-energy rays.

5. The method according to claim 1 wherein the first and second compositions independently comprise:
(A) an organopolysiloxane resin; and
(B) a catalyst for enhancing curing of the organopolysiloxane resin.

6. A method of preparing an article, said method comprising:
applying a first composition having a first refractive index (RI¹) on a substrate to form a first layer comprising the first composition on the substrate;
applying a curing condition to a target portion of the first layer, without applying the curing condition to a non-target portion of the first layer, to form a first contrast layer including at least one cured portion and at least one uncured portion;
applying a second composition having a second refractive index (RI²) on the first contrast layer to form a second layer, the second refractive index (RI²) being the same or different from the first refractive index (RI¹);
applying a curing condition to a target portion of the second layer, without applying the curing condition to a non-target portion of the second layer, to form a second contrast layer including at least one cured portion and at least one uncured portion;
applying a third composition having a third refractive index (RI³) on the second contrast layer to form a third layer, the third refractive index (RI³) being the same or different than the second refractive index (RI²) and being the same or different from the first refractive index (RI¹);
applying a curing condition to a target portion of the third layer, without applying the curing condition to a non-target portion of the third layer, to form a third contrast layer including at least one cured portion and at least one uncured portion; and
selectively removing the at least one uncured portion of the first contrast layer and the at least one uncured portion of the second contrast layer and the at least one uncured portion of the third contrast layer to prepare the article, wherein the article sequentially comprises the substrate, the first contrast layer having the at least one cured portion and not having the at least one uncured portion, the second contrast layer having the at least one cured portion and not having the at least one uncured portion, and the third contrast layer having the at least one cured portion and not having the at least one uncured portion.

7. The method according to claim 6 wherein RI²>RI³ and wherein RI²>RI¹ when measured at a same wavelength of light and temperature.

8. The method according to claim 6 wherein RI³>RI¹ when measured at a same wavelength of light and temperature.

9. The method according to claim 6 wherein RI¹>RI³ when measured at a same wavelength of light and temperature.

10. The method according to claim 6 wherein RI¹=RI³ when measured at a same wavelength of light and temperature.

11. The method according to claim 6 wherein RI¹=RI²=RI³ when measured at a same wavelength of light and temperature.

12. The method according to claim 6 wherein the step of selectively removing the at least one uncured portion of the first contrast layer and the at least one uncured portion of the second contrast layer and the at least one uncured portion of the third contrast layer comprises simultaneously and selectively removing the at least one uncured portion of the first contrast layer and the at least one uncured portion of the second contrast layer and the at least one uncured portion of the third contrast layer.

13. The method according to claim 6 wherein applying a curing condition to the target portion of the first layer comprises irradiating the target portion of the first layer with active-energy rays without irradiating the non-target portion of the first layer with the active-energy rays.

14. The method according to claim 6 wherein applying a curing condition to the target portion of the second layer comprises irradiating the target portion of the second layer with active-energy rays without irradiating the non-target portion of the second layer with the active-energy rays and without irradiating the non-target portion of the first contrast layer with the active energy rays.

15. An article prepared by the method according to claim 1.
